(19) United States
(12) Patent Application Publication
(10) Pub. No.: US 2015/0355550 A1
(43) Pub. Date: Dec. 10, 2015

(54) PRODUCTION METHOD OF SEMICONDUCTOR ELEMENT, AND ION IMPLANTATION METHOD

(71) Applicant: JSR CORPORATION, Tokyo (JP)

(72) Inventor: Taiichi FURUKAWA, Tokyo (JP)

(73) Assignee: JSR CORPORATION, Tokyo (JP)

(21) Appl. No.: 14/830,813

(22) Filed: Aug. 20, 2015

Related U.S. Application Data
(63) Continuation of application No. PCT/JP2014/060655, filed on Apr. 14, 2014.

(30) Foreign Application Priority Data
Apr. 17, 2013 (JP) 2013-087007

(51) Int. Cl. G03F 7/40; G03F 7/20; G03F 7/32; G03F 7/16

(52) U.S. Cl. CPC G03F 7/40; G03F 7/16; G03F 7/20; G03F 7/325

(57) ABSTRACT

A method for producing a semiconductor element includes applying a photoresist composition on a surface of an inorganic substrate to provide a resist film. The photoresist composition includes a polymer comprising an acid-labile group, and an acid generator. The resist film is exposed. The exposed resist film is developed with a developer solution containing an organic solvent to form a negative resist pattern. Ions are implanted into the inorganic substrate using the negative resist pattern as a mask. The photoresist composition preferably further contains a compound including a carboxy group, a sulfo group, a group represented by formula (i), a group capable of generating the carboxy group, the sulfo group or the group represented by the formula (i) by an action of an acid, a lactonic carbonyloxy group or a combination thereof, and having a molecular weight of no greater than 1,000.

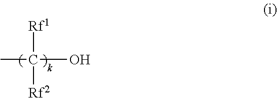

### CROSS-REFERENCE TO RELATED APPLICATIONS

The present application is a continuation application of International Application No. PCT/JP2014/060655, filed Apr. 14, 2014, which claims priority to Japanese Patent Application No. 2013-087007, filed Apr. 17, 2013. The contents of these applications are incorporated herein by reference in their entirety.

### BACKGROUND OF THE INVENTION

1. Field of the Invention

The present invention relates to a production method of a semiconductor element, and an ion implantation method.

2. Discussion of the Background

In chemically amplified photoresist compositions for use in microfabrication by lithography, an acid is generated at a light-exposed site upon irradiation with exposure light, e.g., a far ultraviolet ray such as an ArF excimer laser beam, an electromagnetic wave such as X-ray, a charged particle ray such as an electron beam, or the like. Chemical reactions catalyzed by the acid produce a difference in a rate of dissolution in a developer solution between the light-exposed site and a light-unexposed site, thereby enabling a resist pattern to be formed on a substrate (see Japanese Unexamined Patent Application, Publication Nos. S59-45439, S60-52845 and H2-25850).

The resist patterns thus formed have been utilized in manufacture of semiconductor elements including an ion-implanted inorganic substrate, through using as a mask in implanting ions into a substrate (see Japanese Unexamined Patent Application, Publication Nos. 2004-233656 and 2005-316136). On the other hand, formation of a resist pattern on a stepped substrate made of polysilicon or the like has been increasingly required in manufacture of three-dimensional transistors typified by Fin-FET, and the like, as integrated circuit devices would have further complicated structures in recent years. In such a substrate, there exist a plurality of materials admixed on one piece of substrate, and accordingly in an exposure, the reflectance of exposure light reflected on the surface of the substrate varies from region to region due to the difference of the substrate materials. Thus, there are disadvantages that: formation of a favorable and uniform resist pattern is difficult; scums, i.e., undissolved matter of the resist film, are generated in a space portion of the resist pattern thus formed; peeling of the resist pattern from the substrate is likely to occur; and the like. When such a resist pattern is used, it is difficult to execute the ion implantation in a desired region, and consequently performances, reliability, a process yield and the like of produced semiconductor elements are likely to be adversely affected.

### SUMMARY OF THE INVENTION

According to one aspect of the present invention, a method for producing a semiconductor element includes applying a photoresist composition on a surface of an inorganic substrate to provide a resist film. The photoresist composition includes a polymer comprising an acid-labile group, and an acid generator. The resist film is exposed. The exposed resist film is developed with a developer solution containing an organic solvent to form a negative resist pattern. Ions are implanted into the inorganic substrate using the negative resist pattern as a mask.

According to another aspect of the present invention, an ion implantation method includes applying a photoresist composition on a surface of an inorganic substrate to provide a resist film. The photoresist composition includes a polymer comprising an acid-labile group, and an acid generator. The resist film is exposed. The exposed resist film is developed with a developer solution containing an organic solvent to form a negative resist pattern. Ions are implanted into the inorganic substrate using the negative resist pattern as a mask.

### DESCRIPTION OF THE EMBODIMENTS

According to an embodiment of the invention made for solving the aforementioned problems, a method for producing a semiconductor element includes: providing a resist film on the surface of an inorganic substrate using a photoresist composition (hereinafter, may be also referred to as “resist film-providing step”); exposing the resist film (hereinafter, may be also referred to as “exposure step”); developing the exposed resist film with a developer solution containing an organic solvent to form a negative resist pattern (hereinafter, may be also referred to as “negative resist pattern-forming step”); and implanting ions into the inorganic substrate using the negative resist pattern as a mask (hereinafter, may be also referred to as “ion implantation step”), wherein the photoresist composition (hereinafter, may be also referred to as “photoresist composition (A)”) contains: a polymer including an acid-labile group (hereinafter, may be also referred to as “(A) polymer” or “polymer (A)”); and an acid generator (hereinafter, may be also referred to as “(B) acid generator” or “acid generator (B)”).

Since the method for producing a semiconductor element of the embodiment of the present invention includes the aforementioned steps and the development is executed using the developer solution containing an organic solvent, a resist pattern exhibiting inhibited peeling of the pattern, and inhibited generation of scums can be formed. Thus, by using such a superior resist pattern, a semiconductor element can be produced which includes an inorganic substrate into which ions are implanted in a desired region.

The photoresist composition preferably further contains a compound (hereinafter, may be also referred to as “(C) compound” or “compound (C)”) including at least one selected from the group consisting of a carboxy group, a sulfo group, (a) a group represented by the following formula (i), a group capable of generating the carboxy group, the sulfo group or the group (a) by the action of an acid, and a lactonic carbonyloxy group, the compound having a molecular weight of no greater than 1,000, and the content (i.e., amount) of the compound (C) is preferably no less than 0.1 parts by mass and no greater than 30 parts by mass with respect to 100 parts by mass of the polymer (A).

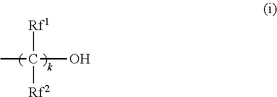

In the formula (i), Rf¹ and Rf² each independently represent a hydrogen atom, a fluorine atom or a perfluoroalkyl group; and k is an integer of 1 to 5, wherein in a case where k is no less than 2, a plurality of Rf¹s may be each identical or different, and a plurality of Rf²s may be each identical or different, and wherein at least one of Rf¹ and Rf² bonding to the carbon atom adjacent to the hydroxy group does not represent a hydrogen atom.

The compound (C) at least includes the above-specified acidic group, the group capable of generating the acidic group by the action of an acid generated from the acid generator (B) upon an exposure, or a lactone ring. It is presumed that at the light-exposed site, this compound (C) inhibits the permeation of an organic solvent-containing developer solution into the resist film, leading an effective improvement of adhesiveness of the resist film to the substrate, whereas at a light-unexposed site, the compound (C) can improve the solubility of the resist film in the organic solvent-containing developer solution. Consequently, according to the method for producing a semiconductor element, the peeling of the pattern and the generation of scums of the resist pattern thus formed can be further inhibited and, in turn, the accuracy of the ion implantation can be improved.

The compound (C) preferably has an alicyclic skeleton. It is presumed that when the compound (C) has an alicyclic skeleton, the aforementioned permeation inhibition effect, adhesiveness and solubility can be enhanced. Consequently, according to the method for producing a semiconductor element, a resist pattern exhibiting further inhibited peeling of the pattern, and further inhibited generation of scums can be formed and, in turn, the accuracy of the ion implantation can be further improved.

The alicyclic skeleton is preferably at least one selected from the group consisting of an adamantane skeleton, a norbornane skeleton and a steroid skeleton.

It is presumed that when the alicyclic skeleton is the above-specified skeleton, the compound (C) can further and effectively enhance the aforementioned permeation inhibition effect, adhesiveness and solubility. Consequently, according to the method for producing a semiconductor element, a resist pattern exhibiting further inhibited peeling of the pattern, and further inhibited generation of scums can be formed and, in turn, the accuracy of the ion implantation can be further improved.

The compound (C) is preferably at least one selected from the group consisting of compounds represented by the following formulae (1), (2-1), (2-2) and (3):

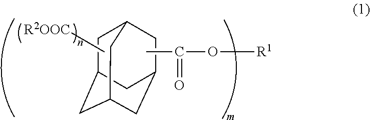

wherein in the formula (1), R¹ represents a hydrogen atom or an acid-labile group having a valency of m; R² represents a hydrogen atom or a monovalent acid-labile group; m is an integer of 1 to 4; and n is an integer of 0 to 15, wherein in a case where R² is present in a plurality of number, a plurality of R^{e}s may be each identical or different,

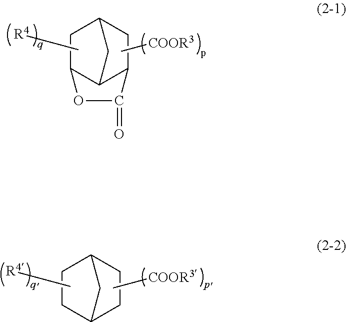

in the formulae (2-1) and (2-2), R³ and R^{3′} each independently represent a hydrogen atom, an alkyl group having 1 to 5 carbon atoms or a monovalent acid-labile group; R⁴ and R^{4′} each independently represent a hydroxy group, an alkoxy group or the group (a); p is an integer of 0 to 10; q is an integer of 0 to 10; p′ is an integer of 0 to 12; q′ is an integer of 0 to 12, wherein the sum of p and q is no less than zero and no greater than 10, the sum of p′ and q′ is no less than 1 and no greater than 12, wherein in a case where R³, R^{3′}, R⁴ and R^{4′} are each present in a plurality of number, a plurality of R³s may be each identical or different, a plurality of R^{3′}s may be each identical or different, a plurality of R⁴s may be each identical or different and a plurality of R^{4′}s may be each identical or different, and wherein at least one of R^{3′} and R^{4′} represents a hydrogen atom, a monovalent acid-labile group or the group (a), and

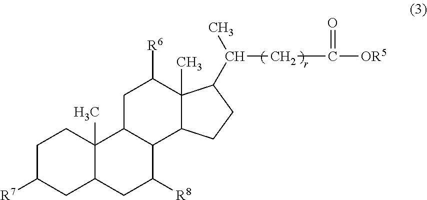

in the formula (3), R⁵ represents a hydrogen atom, a monovalent acid-labile group, or a monovalent organic group including an acid-labile group; R⁶, R⁷ and R⁸ each independently represent a hydrogen atom, —OH or ═O; and r is 1 or 2.

According to the method for producing a semiconductor element, it is presumed that when the above-specified compounds are used as the compound (C), the aforementioned permeation inhibition effect, adhesiveness and solubility can be further improved. Consequently, a resist pattern exhibiting further inhibited peeling of the pattern, and further inhibited generation of scums can be formed and, in turn, the accuracy of the ion implantation can be further improved.

According to another embodiment of the invention made for solving the aforementioned problems, an ion implantation method includes: providing a resist film on the surface of an inorganic substrate using a photoresist composition; exposing the resist film; developing the exposed resist film with a developer solution containing an organic solvent to form a negative resist pattern; and implanting ions into the inorganic substrate using the negative resist pattern as a mask, wherein the photoresist composition contains: a polymer including an acid-labile group; and an acid generator.

According to the ion implantation method of the embodiment of the present invention, the ion implantation can be achieved in a desired region.

The photoresist composition preferably further contains a compound including at least one selected from the group consisting of a carboxy group, a sulfo group, a group (a) represented by the above formula (i), a group capable of generating the carboxy group, the sulfo group or the group (a) by the action of an acid, and a lactonic carbonyloxy group, the compound having a molecular weight of no greater than 1,000, and the content of the compound is preferably no less than 0.1 parts by mass and no greater than 30 parts by mass with respect to 100 parts by mass of the polymer.

The compound preferably has an alicyclic skeleton.

The alicyclic skeleton is preferably at least one selected from the group consisting of an adamantane skeleton, a norbornane skeleton and a steroid skeleton.

The compound is preferably at least one selected from the group consisting of compounds represented by the above formulae (1), (2-1), (2-2) and (3).

As explained in the foregoing, the method for producing a semiconductor element according to the embodiment of the present invention enables a resist pattern exhibiting inhibited peeling of the pattern, and inhibited generation of scums to be formed, and by using such a superior resist pattern as a mask, a semiconductor element can be produced which includes an inorganic substrate into which ions are implanted in a desired region. The ion implantation method according to the embodiment of the present invention enables ions to be implanted into a desired region of an inorganic substrate. Therefore, the embodiments of the present invention can be suitably used in manufacture of semiconductor products, and the like, and can improve performances, reliability, a process yield and the like of the products. Hereinafter, embodiments of the present invention will be described in detail.

### Production Method of Semiconductor Element and Ion Implantation Method

A method for producing a semiconductor element and an ion implantation method according to embodiments of the present invention include the resist film-providing step, the exposure step, the negative resist pattern-forming step and the ion implantation step. In the resist film-providing step, the photoresist composition (A) is used.

Hereinafter, each step will be explained. The photoresist composition (A) will be described later.

### Resist Film-Providing Step

In this step, a resist film is provided on the surface of the inorganic substrate using the photoresist composition (A). The material of the inorganic substrate is exemplified by silicon, silicon oxide, silicon nitride, silicon nitride oxide, and the like. Also, substrates obtained by coating the aforementioned substrates with aluminum or the like, etc. can be used. Of these, silicon, silicon oxide and silicon nitride are preferred.

Examples of the application procedure include spin coat (spin-coating), cast coating, roll coating, and the like. It is to be noted that the film thickness of the resist film provided is typically 10 nm to 5,000 nm, preferably 50 nm to 2,000 nm, and still more preferably 100 nm to 1,000 nm.

After the application of the photoresist composition (A), prebaking (PB) may be executed to evaporate the solvent in the coating film, as needed. The PB temperature may be appropriately selected depending on the formulation of the photoresist composition (A), and is typically 30° C. to 200° C., and preferably 50° C. to 150° C. The time period of the PB is typically 5 sec to 600 sec, and preferably 10 sec to 300 sec.

In order to prevent influences of basic impurities etc., included in the environment atmosphere, a protective film may be provided on the resist film, as disclosed in, for example, Japanese Unexamined Patent Application, Publication No. H5-188598, or the like. Furthermore, in order to prevent an outflow of the acid generator or the like from the resist film, a protective film for liquid immersion may be provided on the resist layer, as disclosed in, for example, Japanese Unexamined Patent Application, Publication No. 2005-352384, or the like. It is to be noted that these techniques may be used in combination.

### Exposure Step

In this step, the resist film provided in the resist film-providing step is exposed. The exposure may be executed in desired regions through a mask having a given pattern. In this exposure, a reduced projection exposure may be carried out. An isolated trench (iso-trench) pattern can be formed by using an isolated line (iso-line) pattern mask as a mask. Also, the exposure may be carried out at least twice by using mask(s) having a desired pattern. For example, a circular contact hole pattern can be formed by using a line-and-space pattern mask as a mask, and executing a second exposure after a first exposure such that the lines formed through the first exposure are perpendicular to the lines formed through the second exposure. When the exposure is executed two or more times, a plurality of exposures are preferably executed continuously.

The exposure may be executed through a liquid immersion liquid. The liquid immersion liquid is exemplified by water, fluorine-containing inert liquid, and the like. It is preferred that the liquid immersion liquid is transparent to the exposure wavelength, and has a temperature coefficient of the refractive index as small as possible such that distortion of an optical image projected onto the film is minimized. In particular, when an ArF excimer laser beam (wavelength: 193 nm) is used as an exposure light source, water is preferably used in light of its availability and ease of handling, in addition to the aforementioned respects. When water is used as the liquid immersion liquid, a slight amount of an additive may be added which reduces the surface tension of water and provides surfactant power. It is preferred that the additive hardly dissolves the resist layer on the wafer and has a negligible influence on an optical coating of an inferior face of a lens. Distilled water is preferably used.

Various electromagnetic waves or charged particle rays may be used as an exposure light for use in the exposure, and the exposure light may be appropriately selected in accordance with the type of the acid generator (B). The electromagnetic waves are exemplified by ultraviolet rays, far ultraviolet rays, visible light rays, X-rays, γ-rays and the like, and the charged particle rays are exemplified by electron beams, α-rays and the like. Of these, electromagnetic waves are preferred, far infrared rays are more preferred, whereas far ultraviolet rays typified by an ArF excimer laser beam and a KrF excimer laser (wavelength: 248 nm) are preferred, and an ArF excimer laser is more preferred. The exposure conditions such as an exposure dose may be appropriately selected in accordance with the formulation of the photoresist composition (A), the type of the additive, and the like.

Moreover, it is preferred that post exposure baking (PEB) is executed after the exposure. When the PEB is executed, a dissociation reaction of the acid-labile group in the polymer (A) of the photoresist composition (A) can smoothly proceed. The PEB temperature is typically 30° C. to 200° C., preferably 50° C. to 170° C., and more preferably 80° C. to 130° C.

### Negative Resist Pattern-Forming Step

In this step, the resist film exposed in the exposure step is developed with a developer solution containing an organic solvent, whereby a negative resist pattern is formed. The developer solution containing an organic solvent is not particularly limited as long as it contains an organic solvent. The organic solvent is preferably at least one selected from the group consisting of an alcohol solvent, an ether solvent, a ketone solvent, an amide solvent, an ester solvent and a hydrocarbon solvent.

Examples of the alcohol solvent include:

monohydric alcohol solvents such as methanol, ethanol, n-propanol, iso-propanol, n-butanol, iso-butanol, sec-butanol, tert-butanol, n-pentanol, iso-pentanol, 2-methylbutanol, sec-pentanol, tert-pentanol, 3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol and diacetone alcohol;

polyhydric alcohol solvents such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol and tripropylene glycol;

polyhydric alcohol partial ether solvents such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether and dipropylene glycol monopropyl ether; and the like.

Examples of the ether solvent include:

dialkyl ether solvents such as diethyl ether, dipropyl ether and dibutyl ether;

aromatic ring-containing ethers such as diphenyl ether and anisole; and the like.

Examples of the ketone solvent include:

chain ketone solvents such as acetone, methyl ethyl ketone, methyl n-propyl ketone, methyl n-butyl ketone, diethyl ketone, methyl iso-butyl ketone, methyl n-pentyl ketone (2-heptanone), ethyl n-butyl ketone, methyl n-hexyl ketone, di-iso-butyl ketone and trimethylnonanone;

cyclic ketone solvents such as cyclopentanone, cyclohexanone, cycloheptanone, cyclooctanone and methylcyclohexanone;

2,4-pentanedione, acetonylacetone and acetophenone; and the like.

Examples of the amide solvent include:

chain amide solvents such as N-methylformamide, N,N-dimethylformamide, N,N-diethylformamide, acetamide, N-methylacetamide, N,N-dimethylacetamide and N-methylpropionamide;

cyclic amide solvents such as N-methylpyrrolidone and N,N′-dimethylimidazolidinone; and the like.

Examples of the ester solvent include:

acetic acid ester solvents such as methyl acetate, ethyl acetate, n-propyl acetate, iso-propyl acetate, n-butyl acetate, iso-butyl acetate, sec-butyl acetate, n-pentyl acetate, i-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate and ethyl acetoacetate;

polyhydric alcohol partial ether acetate solvents such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate and dipropylene glycol monoethyl ether acetate;

glycol diacetate, methoxytriglycol acetate, ethyl propionate, n-butyl propionate, iso-amyl propionate, diethyl oxalate, di-n-butyl oxalate, methyl lactate, ethyl lactate, n-butyl lactate, n-amyl lactate, diethyl malonate, dimethyl phthalate, diethyl phthalate, etc.;

lactone solvents such as γ-butyrolactone and γ-valerolactone;

carbonate solvents such as diethyl carbonate and propylene carbonate; and the like.

Examples of the hydrocarbon solvent include:

aliphatic hydrocarbon solvents such as n-pentane, iso-pentane, n-hexane, iso-hexane, n-heptane, iso-heptane, 2,2,4-trimethylpentane, n-octane, iso-octane, cyclohexane and methylcyclohexane;

aromatic hydrocarbon solvents such as benzene, toluene, xylene, mesitylene, ethylbenzene, trimethylbenzene, methylethylbenzene, n-propylbenzene, iso-propylbenzene, diethylbenzene, iso-butylbenzene, triethylbenzene, di-iso-propylbenzene and n-amylnaphthalene; and the like.

Of these, ester solvents, ketone solvents and ether solvents are preferred, acetic acid ester solvents, chain ketone solvents and aromatic ring-containing ether solvent are more preferred, and butyl acetate, isoamyl acetate, benzyl acetate, methyl amyl ketone and anisole are still more preferred.

These organic solvents may be used either alone, or as a mixture of two or more thereof.

The content of the organic solvent in the developer solution is preferably no less than 80% by mass, more preferably no less than 90% by mass, still more preferably no less than 95% by mass, and particularly preferably no less than 99% by mass. When the content of the organic solvent in the developer solution falls within the above range, a contrast of the pattern resulting from the exposure, i.e., depending on being exposed or unexposed, can be improved, and consequently, peeling of the pattern and generation of scums in the resist pattern can be further inhibited. It is to be noted that a component other than the organic solvent is exemplified by water, silicone oil, and the like.

An appropriate amount of a surfactant may be added to the developer solution as needed. For example, an ionic or nonionic fluorine-containing surfactant and/or an ionic or nonionic silicon-containing surfactant or the like may be used as the surfactant.

In addition, the developer solution may contain a nitrogen-containing compound. When the developer solution contains the nitrogen-containing compound, the nitrogen-containing compound can interact with a carboxy group or the like that is generated in a structural unit (I) of the polymer (A) in the resist film by the action of an acid generated from the acid generator (B), and can further increase the insolubility of the light-exposed site in the organic solvent. In this regard, the interaction of the nitrogen-containing compound with the carboxy group or the like as referred to means that the nitrogen-containing compound reacts with the carboxy group or the like to form a salt, an ionic bond, or the like.

Examples of the nitrogen-containing compound include:

(cyclo)alkylamine compounds, e.g., mono(cyclo)alkylamines such as n-octylamine and cyclohexylamine;

di(cyclo)alkylamines such as di-n-octylamine and dicyclohexylamine;

tri(cyclo)alkylamines such as tri-n-octylamine and tricyclohexylamine;

nitrogen-containing heterocyclic compounds such as imidazole, piperidine and morpholine;

amide group-containing compounds such as N,N-dimethylformamide and N-t-butoxycarbonyl-di-n-octylamine;

urea compounds such as urea, 1,1-dimethylurea and tri-n-butylthiourea; and the like.

Of these, as the nitrogen-containing compound, (cyclo)alkylamine compounds are preferred, trialkylamine compounds are more preferred, and tri-n-octylamine is still more preferred.

The content of the nitrogen-containing compound in the developer solution is preferably no greater than 10% by mass, more preferably 0.1% by mass to 5% by mass, and still more preferably 0.2% by mass to 3% by mass.

Examples of the development method include: a dip method in which the substrate is immersed for a given time period in the developer solution charged in a container; a puddle method in which the developer solution is placed to form a dome-shaped bead by way of the surface tension on the surface of the substrate for a given time period to conduct a development; a spray method in which the developer solution is sprayed onto the surface of the substrate; a dynamic dispensing method in which the developer solution is continuously applied onto the substrate that is rotated at a constant speed while scanning with a developer solution-application nozzle at a constant speed; and the like.

In the method for producing a semiconductor element and the ion implantation method, the resist film is preferably washed with a rinse agent after the development in the negative resist pattern-forming step. Various organic solvents may be used as the rinse agent, but hydrocarbon solvents, ketone solvents, ester solvents, alcohol solvents and amide solvents are preferred, alcohol solvents and ether solvents are more preferred, monovalent alcohol solvents having 6 to 8 carbon atoms and dialkyl ether solvents having 6 to 12 carbon atoms are still more preferred, and 4-methyl-2-pentanol, 1-hexanol, diisoamyl ether are particularly preferred.

The rinse agent may be used either alone, or as a mixture of two or more thereof. The moisture content in the rinse agent is preferably no greater than 10% by mass, more preferably no greater than 5% by mass, and still more preferably no greater than 3% by mass. When the moisture content is no greater than 10% by mass, favorable development performances may be attained. It is to be noted that the rinse agent may contain a surfactant.

The method for the washing treatment is exemplified by: a spin-coating method in which the rinse agent is continuously applied onto the substrate that is rotated at a constant speed; a dipping method in which the substrate is immersed for a given time period in the rinse agent charged in a container; a spray method in which the rinse agent is sprayed onto the surface of the substrate; and the like.

### Ion Implantation Step

In this step, ions are implanted into the inorganic substrate using as a mask, the resist pattern formed in the negative resist pattern-forming step. The ion implantation may be carried out according to a well-known method using a well-known ion implantation apparatus.

After the aforementioned steps, an ion-implanted substrate can be obtained. The method for producing a semiconductor element and the ion implantation method according to the embodiments of the present invention enable a resist pattern exhibiting inhibited peeling of the pattern, and inhibited generation of scums to be formed, and by using such a superior resist pattern as a mask, an inorganic substrate into which ions are implanted in a desired region can be obtained.

### Photoresist Composition (A)

The photoresist composition (A) for use in the method for producing a semiconductor element and the ion implantation method according to the embodiment of the present invention contains (A) a polymer and (B) an acid generator. The photoresist composition (A) favorably contains (C) a compound, (D) an acid diffusion controller and (E) a solvent, and may contain other component within a range not leading to impairment of the effects of the present invention. Hereinafter, each component will be explained.

### (A) Polymer

The polymer (A) includes an acid-labile group. The “acid-labile group” as referred to herein means a group that substitutes for a hydrogen atom of an acidic group such as a carboxy group, a hydroxy group or a sulfo group and is dissociated by the action of an acid. Due to the polymer (A) including the acid-labile group, when the acid-labile group at a light-exposed site is the dissociated by the action of the acid generated from the acid generator (B), the polymer (A) increases in polarity and becomes hardly soluble in the developer solution containing an organic solvent. Thus, a negative resist pattern can be obtained in the method for producing a semiconductor element and the ion implantation method described above. The polymer (A) is not particularly limited as long as it includes an acid-labile group. The position of the acid-labile group is not particularly limited, and the acid-labile group may be present in the main chain of the polymer (A) and/or at an end thereof; however, it is preferred that the polymer (A) has a structural unit (I) that includes an acid-labile group.

The polymer (A) may have, in addition to the structural unit (I): a structural unit (II) that includes at least one selected from the group consisting of a lactone structure, a cyclic carbonate structure and a sultone structure; and a structural unit (III) that includes a hydroxy group, and may have a structural unit other than these structural units. The polymer (A) may have either one, or two or more types of each structural unit. Hereinafter, each structural unit will be explained.

### Structural Unit (I)

The structural unit (I) includes an acid-labile group. Due to the polymer (A) having the structural unit (I), the acid-labile group can be incorporated into the polymer (A) effectively.

The structural unit (I) is not particularly limited as long as an acid-labile group is included in the structural unit; however, a structural unit (I-1) represented by the following formula (4-1) and/or a structural unit (I-2) represented by the following formula (4-2) are/is preferred.

Structural units (I-1) and (I-2)

The structural unit (I-1) is represented by the following formula (4-1). The structural unit (I-2) is represented by the following formula (4-2).

Since the acid-labile group included in the structural units (I-1) and (I-2) has high dissociability, resistance to dissolution in a developer solution may be further improved at a light-exposed site. As a result, the peeling of the pattern may be further inhibited.

In addition, since monomers that give the structural units (I-1) and (I-2) have superior copolymerizability, the proportion of the acid-labile group in the polymer (A) can be conveniently adjusted so as to give a desired proportion.

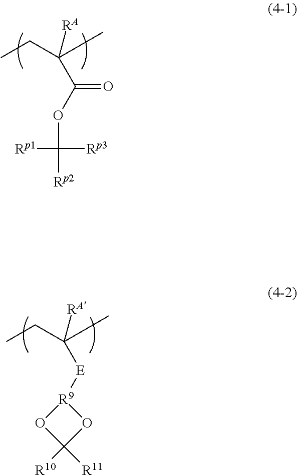

In the above formula (4-1), R^{A} represents a hydrogen atom, a fluorine atom, a methyl group or a trifluoromethyl group; R^{p1}, R^{p2} and R^{p3} each independently represent an alkyl group having 1 to 6 carbon atoms or a monovalent alicyclic hydrocarbon group having 4 to 20 carbon atoms, wherein R^{p2} and R^{p3} may taken together represent a divalent alicyclic hydrocarbon group having 4 to 20 carbon atoms, together with the carbon atom to which R^{p2} and R^{p3} bond.

In the above formula (4-2), R^{A′} represents a hydrogen atom, a fluorine atom, a methyl group or a trifluoromethyl group; E represents a divalent linking group having a hetero atom; R⁹ represents a trivalent hydrocarbon group having 1 to 20 carbon atoms; R¹⁰ and R¹¹ each independently represent a hydrogen atom or a monovalent hydrocarbon group having 1 to 20 carbon atoms, wherein R¹⁰ and R¹¹ may taken together represent a divalent alicyclic hydrocarbon group having 4 to 20 carbon atoms, together with the carbon atom to which R¹⁰ and R¹¹ bond.

Examples of the alkyl group having 1 to 6 carbon atoms which may be represented by R^{p1}, R^{p2} or R^{p3} include a methyl group, an ethyl group, a n-propyl group, an i-propyl group, a n-butyl group, a 2-methylpropyl group, a 1-methylpropyl group, a t-butyl group, and the like.

Examples of the monovalent alicyclic hydrocarbon group having 4 to 20 carbon atoms which may be represented by R^{p1}, R^{p2} or R^{p3} include:

polycyclic alicyclic hydrocarbon groups such as a norbornyl group and an adamantyl group;

monocyclic alicyclic hydrocarbon groups such as a cyclopentane and a cyclohexane; and the like.

Examples of the divalent alicyclic hydrocarbon group having 4 to 20 carbon atoms which may be taken together represented by R^{p2} and R^{p3} include:

polycyclic alicyclic hydrocarbon groups such as a norbornanediyl group and an adamantanediyl group;

monocyclic alicyclic hydrocarbon groups such as a cyclopentanediyl group and a cyclohexanediyl group; and the like.

As the structural unit (I-1), structural units represented by the following formulae (4-1-1) to (4-1-5) (hereinafter, may be also referred to as “structural units (I-1-1) to (I-1-5)”) are preferred.

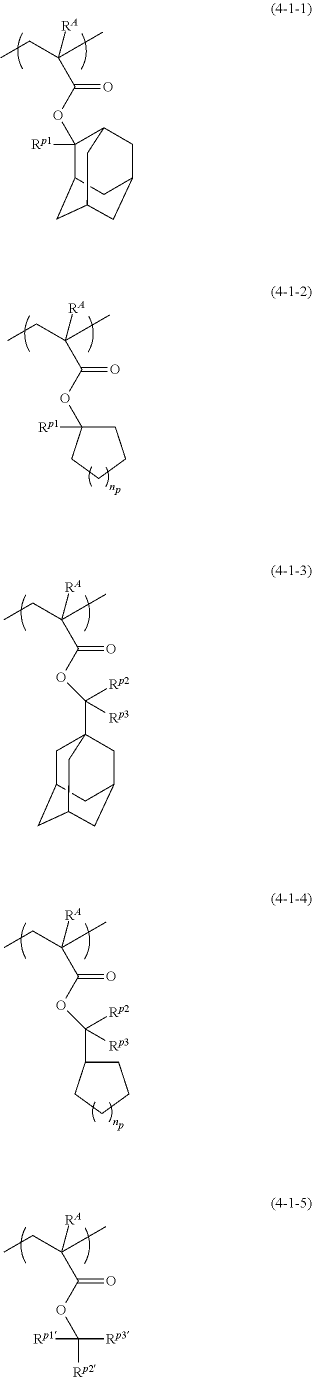

In the above formulae (4-1-1) to (4-1-5), R^{A}, R^{p1}, R^{p2} and R^{p3} are as defined in the above formula (4-1); R^{p1′}, R^{p2′} and R^{p3′} each independently represent an alkyl group having 1 to 6 carbon atoms; and nₚ is an integer of 1 to 4.

Preferably, nₚ is 1, 2 or 4, and more preferably 1 or 2.

Examples of the alkyl group having 1 to 6 carbon atoms represented by R^{p1′}, R^{p2′} or R^{p3′} include alkyl groups having 1 to 6 carbon atoms similar to those exemplified in connection with R^{p1}, R^{p2} and R^{p3}, and the like. Of these, a methyl group and an ethyl group are preferred, and a methyl group is more preferred.

Examples of the structural units (I-1) and (I-1-1) to (I-1-5) include structural units represented by the following formulae, and the like.

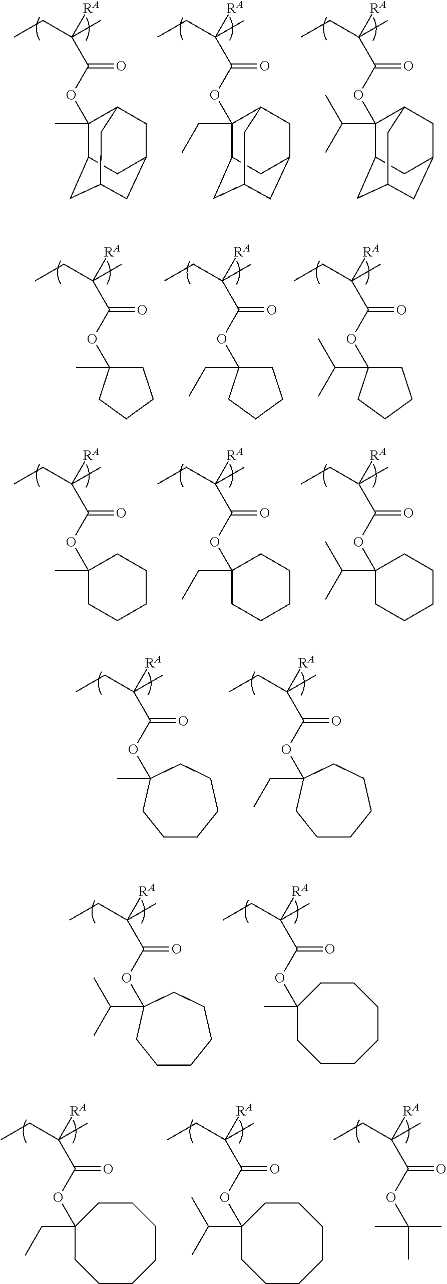

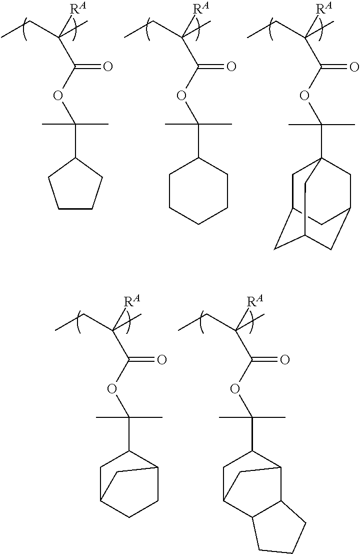

In the above formulae, R^{A} is as defined in the above formula (4-1).

Of these, the structural units (I-1-1), (I-1-2) and (I-1-5) are preferred, the structural units (I-1-1) and (I-1-5) are more preferred, a structural unit derived from 1-alkyl-1-cyclopentyl(meth)acrylate, a structural unit derived from 1-alkyl-1-cyclohexyl(meth)acrylate, and a structural unit derived from t-alkyl(meth)acrylate are still more preferred, and a structural unit derived from 1-methyl-1-cyclopentyl(meth)acrylate, a structural unit derived from 1-ethyl-1-cyclohexyl(meth)acrylate, a structural unit derived from t-butyl(meth)acrylate are particularly preferred.

Examples of the divalent linking group having a hetero atom, which is represented by E, include —O—, —NH—, —S—, —CO—, —CS—, or a combination of two or more thereof, or a group obtained by combining either one, or two or more types of of these groups with either one, or two or more types of divalent hydrocarbon groups, and the like.

The trivalent hydrocarbon group having 1 to 20 carbon atoms represented by R⁹ is exemplified by a trivalent chain hydrocarbon group having 1 to 20 carbon atoms, a trivalent alicyclic hydrocarbon group having 3 to 20 carbon atoms, a trivalent aromatic hydrocarbon group having 6 to 20 carbon atoms, and the like.

Examples of the trivalent chain hydrocarbon group include an ethanetriyl group, a propanetriyl group, a butanetriyl group, and the like.

Examples of the trivalent alicyclic hydrocarbon group include a cyclopentanetriyl group, a cyclohexanetriyl group, a methylcyclopentanetriyl group, and the like.

Examples of the trivalent aromatic hydrocarbon group include a benzenetriyl group, a toluenetriyl group, a xylenetriyl group, a naphthalenetriyl group, and the like.

Of these, a trivalent chain hydrocarbon group is preferred, and a propanetriyl group is more preferred.

The monovalent hydrocarbon group having 1 to 20 carbon atoms which may be represented by R¹⁰ or R¹¹ is exemplified by a monovalent chain hydrocarbon group having 1 to 20 carbon atoms, a monovalent alicyclic hydrocarbon group having 3 to 20 carbon atoms, and a monovalent aromatic hydrocarbon group having 6 to 20 carbon atoms.

Examples of the monovalent chain hydrocarbon group include: alkyl groups such as a methyl group, an ethyl group, a n-propyl group, an i-propyl group, a n-butyl group, an i-butyl group, a sec-butyl group and a t-butyl group; and the like.

Examples of the monovalent alicyclic hydrocarbon group include: monocyclic alicyclic hydrocarbon groups such as a cyclopropyl group, a cyclobutyl group, a cyclopentyl group and a cyclohexyl group; polycyclic alicyclic hydrocarbon groups such as a norbornyl group and an adamantyl group; and the like.

Examples of the monovalent aromatic hydrocarbon group include: aryl groups such as a phenyl group, a tolyl group, a xylyl group, a mesityl group and a naphthyl group; aralkyl groups such as a benzyl group and a phenethyl group; and the like.

Examples of the divalent alicyclic hydrocarbon group having 4 to 20 carbon atoms which may be taken together represented by R¹⁰ and R¹¹ include divalent alicyclic hydrocarbon groups similar to those exemplified in connection with the divalent alicyclic hydrocarbon group which may be taken together represented by R^{p2} and R^{p3}, and the like.

Of these, as R¹⁰ and R¹¹, monovalent chain hydrocarbon groups are preferred, alkyl groups are more preferred, alkyl groups having 1 to 3 carbon atoms are still more preferred, and a methyl group is particularly preferred.

Examples of the structural unit (I-2) include structural units represented by the following formulae, and the like.

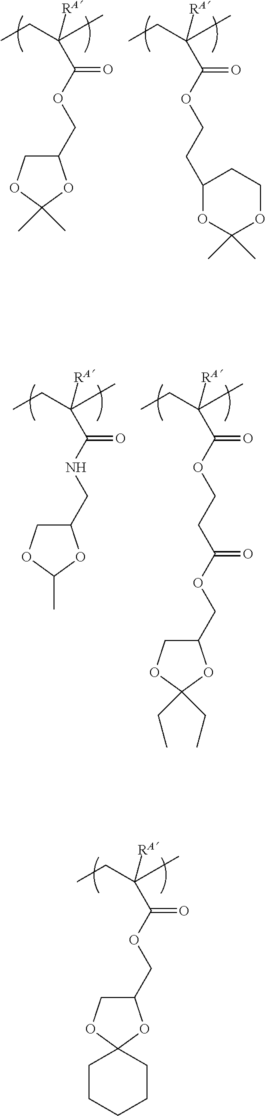

In the above formulae, R^{A′} is as defined in the above formula (4-2).

The proportion of the structural unit (I) is preferably 10 mol % to 90 mol %, more preferably 20 mol % to 80 mol %, and still more preferably 30 mol % to 70 mol % with respect to the total structural units constituting the polymer (A). When the proportion of the structural unit (I) falls within the above range, the peeling of the pattern and the generation of scums in the resist pattern formed in the method for producing a semiconductor element and the ion implantation method can be further inhibited. When the proportion of the structural unit (I) is less than the lower limit, the pattern formability may be deteriorated. Also, when the proportion of the structural unit (I) is greater than the upper limit, the pattern formability may be deteriorated.

### Structural Unit (II)

The structural unit (II) includes at least one selected from the group consisting of a lactone structure, a cyclic carbonate structure and a sultone structure. When the polymer (A) further has the structural unit (II), adhesiveness of the resist film to the substrate or the like may be further improved, and consequently the peeling of the resist pattern formed in the method for producing a semiconductor element and the ion implantation method can be further inhibited. In addition, at the light-unexposed site, the solubility of the resist film in a developer solution can be increased, leading to further inhibition of the generation of scums. The lactone structure as referred to herein means a ring structure that includes a ring (lactone ring) having a bond represented by —O—C(O)—. The cyclic carbonate structure as referred to means a ring structure that that includes a ring (cyclic carbonate ring) having a bond represented by —O—C(O)—O—. Moreover, the sultone structure as referred to means a ring structure that that includes a ring (sultone ring) having a bond represented by —S(O)₂—O—.

Examples of the structural unit (II) include structural units represented by the following formulae, and the like.

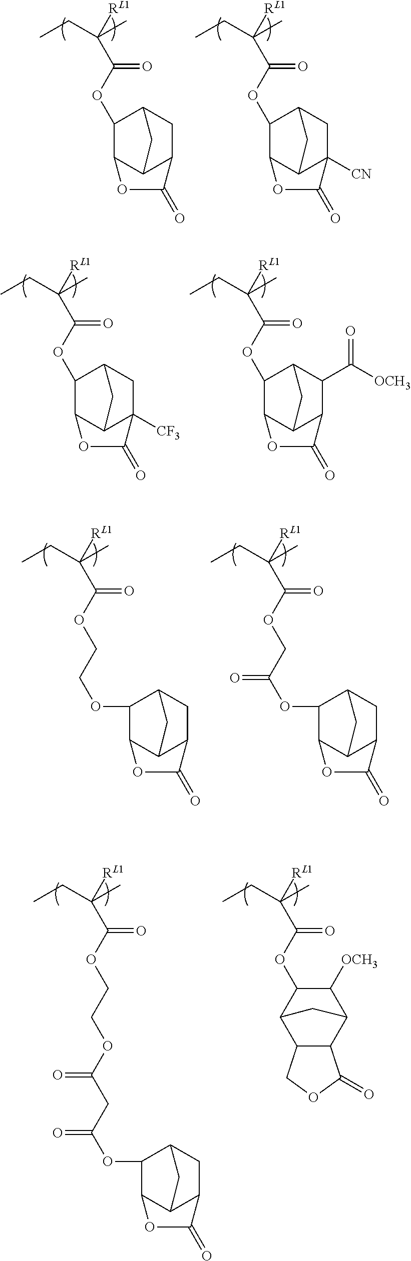

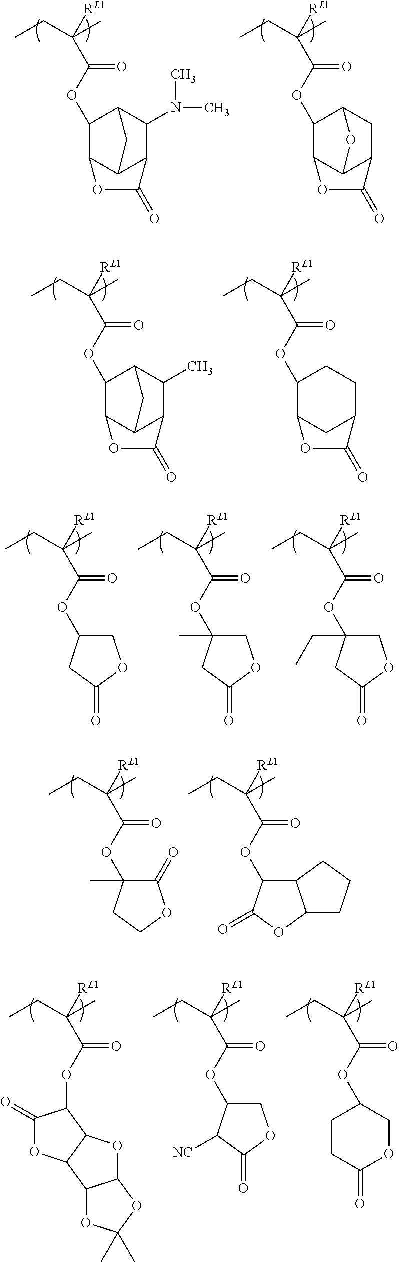

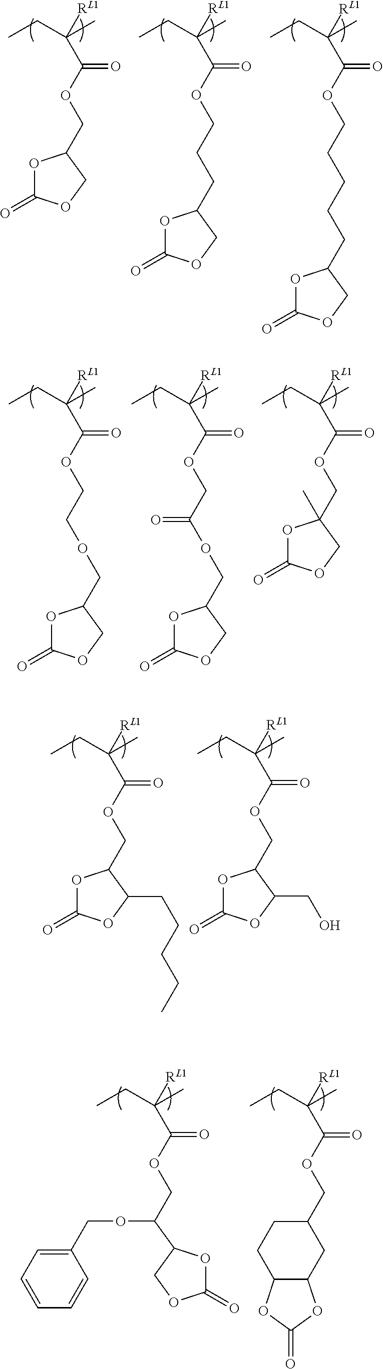

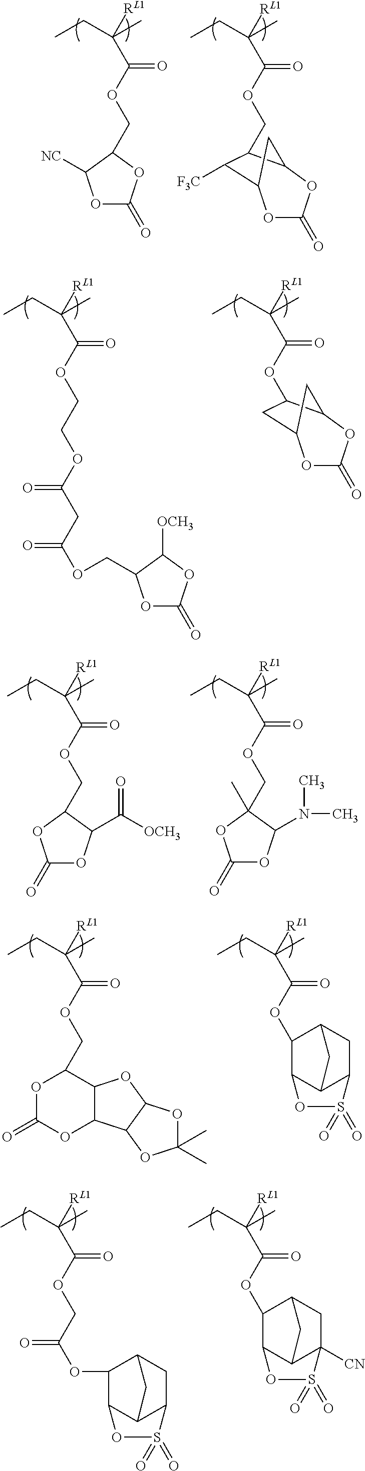

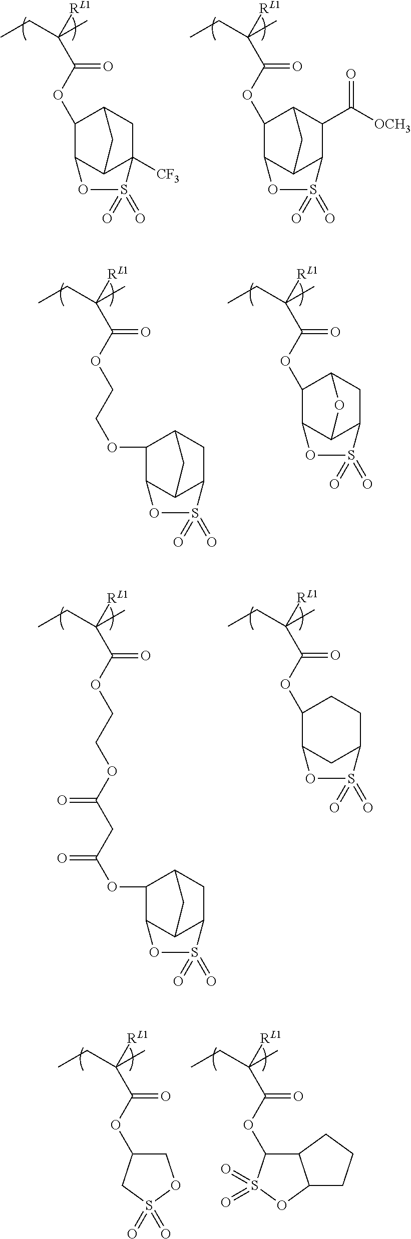

In the above formulae, R^{L1} represents a hydrogen atom, a fluorine atom, a methyl group or a trifluoromethyl group.

Of these, the structural unit (II) is preferably a structural unit that includes a lactone structure, more preferably a structural unit that includes a norbornanelactone structure, and still more preferably a structural unit derived from norbornanelactonyl(meth)acrylate, or a structural unit derived from norbornanelactonyloxycarbonylmethyl(meth)acrylate.

The proportion of the structural unit (II) is preferably 0 mol % to 90 mol %, more preferably 20 mol % to 70 mol %, and still more preferably 25 mol % to 60 mol % with respect to the total structural units constituting the polymer (A). When the proportion of the structural unit (II) falls within the above range, the peeling of the resist pattern formed in the method for producing a semiconductor element and the ion implantation method can be further inhibited. When the proportion of the structural unit (II) is greater than the upper limit, the pattern formability of the resist pattern thus formed may be deteriorated.

### Structural Unit (III)

The structural unit (III) includes a hydroxy group. When the polymer (A) further has the structural unit (III), the adhesiveness of the resist film to the substrate may be improved, and consequently the peeling of the resist pattern formed in the method for producing a semiconductor element and the ion implantation method can be further inhibited. In addition, at the light-unexposed site, the solubility of the resist film in a developer solution can be increased, leading to further inhibition of the generation of scums.

The hydroxy group may be an alcoholic hydroxy group or a phenolic hydroxy group. The polymer (A) having a structural unit that includes a phenolic hydroxy group can be suitably used for a KrF exposure.

The structural unit (III) is exemplified by structural units represented by the following formulae.

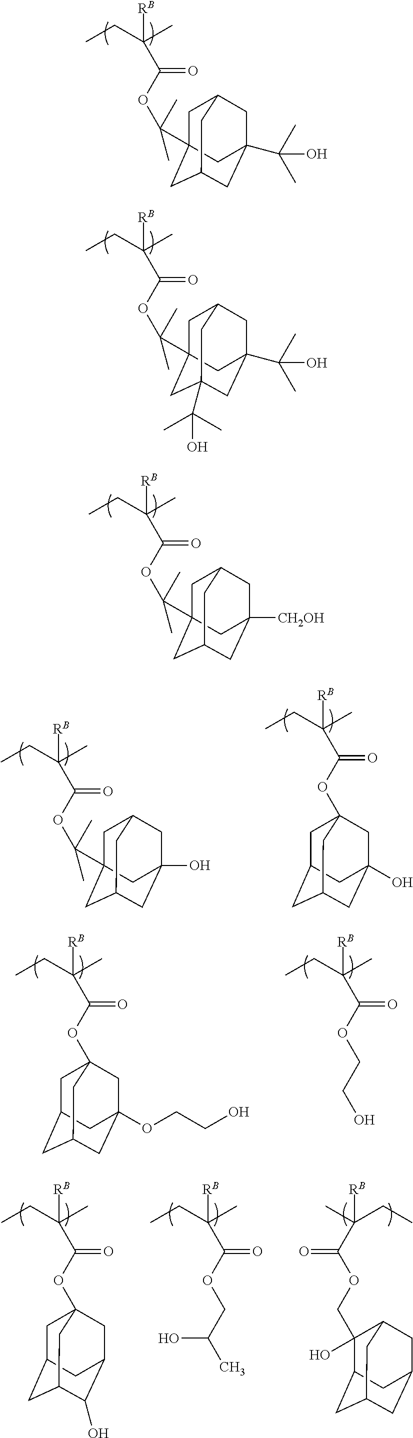

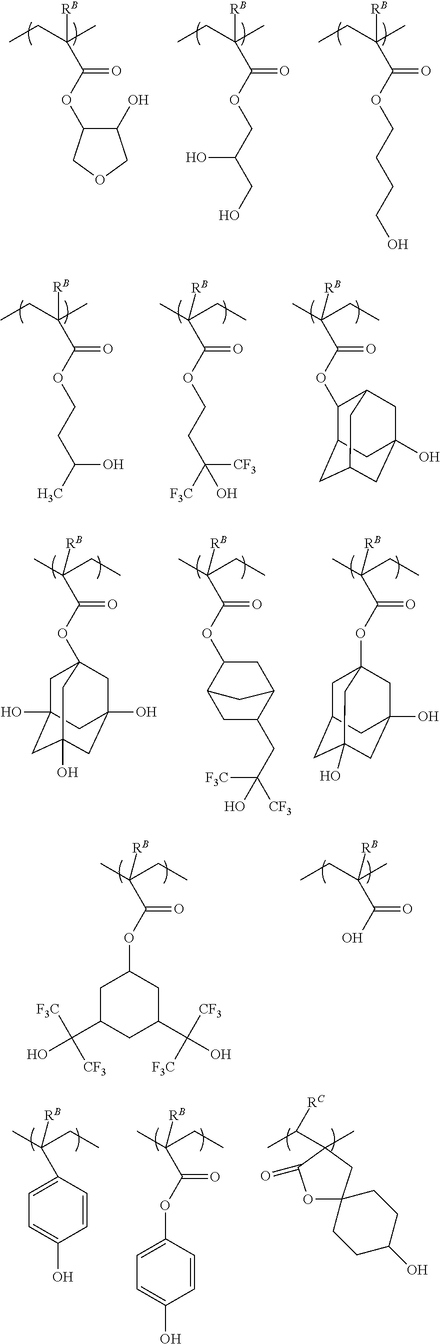

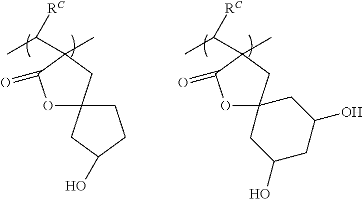

In the above formulae, R^{B} represents a hydrogen atom, a fluorine atom, a methyl group or a trifluoromethyl group; and R^{C} represents a hydrogen atom or a methyl group.

Of these, structural units that include an adamantane skeleton, and structural units that include a phenol structure are preferred, and structural units derived from 3-hydroxyadamantyl(meth)acrylate, 3-(hydroxyethoxy)adamantyl(meth)acrylate, 4-hydroxystyrene and 4-hydroxy-α-methylstyrene are more preferred.

The proportion of the structural unit (III) is preferably 0 mol % to 60 mol %, more preferably 5 mol % to 50 mol %, and still more preferably 5 mol % to and 25 mol % with respect to the total structural units constituting the polymer (A). When the proportion of the structural unit (III) falls within the above range, the peeling of the resist pattern formed in the method for producing a semiconductor element and the ion implantation method can be further inhibited. When the proportion of the structural unit (III) is greater than the upper limit, the pattern formability may be deteriorated.

Other Structural Unit

The polymer (A) may further have, for example, a structural unit that includes a polar group such as a cyano group and a ketonic carbonyl group other than the hydroxy group, and the like as other structural unit except for the structural units (I) to (III). The total proportion of the other structural unit(s) is typically no greater than 30 mol %, and preferably no greater than 20 mol % with respect to the total structural units constituting the polymer (A).

The content of the polymer (A) is preferably no less than 70% by mass, and more preferably no less than 80% by mass with respect to the total solid content of the photoresist composition (A).

### Synthesis Method of Polymer (A)

The polymer (A) can be produced, for example, by polymerizing monomer(s) corresponding to each given structural unit in an appropriate solvent with the use of a radical polymerization initiator.

The radical polymerization initiator is exemplified by: azo radical initiators such as azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile) and dimethyl 2,2′-azobisisobutyrate; peroxide radical initiators such as benzoyl peroxide, t-butyl hydroperoxide and cumene hydroperoxide; and the like. Of these, AIBN and dimethyl 2,2′-azobisisobutyrate are preferred. These radical initiators may be used either alone, or as a mixture of two or more thereof.

Examples of the solvent for use in the polymerization include:

alkanes such as n-pentane, n-hexane, n-heptane, n-octane, n-nonane and n-decane;

cycloalkanes such as cyclohexane, cycloheptane, cyclooctane, decalin and norbornane;

aromatic hydrocarbons such as benzene, toluene, xylene, ethylbenzene and cumene;

halogenated hydrocarbons such as chlorobutanes, bromohexanes, dichloroethanes, hexamethylene dibromide and chlorobenzene;

saturated carboxylic acid esters such as ethyl acetate, n-butyl acetate, i-butyl acetate and methyl propionate;

ketones such as acetone, methyl ethyl ketone, 4-methyl-2-pentanone and 2-heptanone;

ethers such as tetrahydrofuran, dimethoxyethanes and diethoxyethanes;

alcohols such as methanol, ethanol, 1-propanol, 2-propanol and 4-methyl-2-pentanol; and the like. These solvents may be used either alone, or two or more types thereof may be used in combination.

The reaction temperature in the polymerization is typically 40° C. to 150° C., and preferably 50° C. to 120° C. The reaction time period is typically 1 hour to 48 hrs, and preferably 1 hour to 24 hrs.

Although the polystyrene equivalent weight average molecular weight (Mw) of the polymer (A) as determined by gel permeation chromatography (GPC) is not particularly limited, the Mw of the polymer (A) is typically 1,000 to no greater than 100,000, preferably 2,000 to 50,000, still more preferably 3,000 to 30,000, and particularly preferably 4,000 to 20,000. When the Mw of the polymer (A) is less than the lower limit, the heat resistance of the resulting resist film may be deteriorated. When the Mw of the polymer (A) is greater than the upper limit, the developability of the resist film may be deteriorated.

The ratio (Mw/Mn) of the Mw to the polystyrene equivalent number average molecular weight (Mn) as determined by GPC of the polymer (A) is typically 1 to 5, preferably 1 to 3, and more preferably 1 to 2.

### (B) Acid Generator

The acid generator (B) is a substance that generates an acid upon irradiation with exposure light. The acid thus generated allows the acid-labile group present in the polymer (A) to be dissociated, thereby generating a carboxy group or the like. As a result, the polymer (A) becomes hardly soluble in the developer solution containing an organic solvent. In this regard, the exposure light is exemplified by: electromagnetic waves such as ultraviolet rays, visible light rays, far ultraviolet rays, X-rays and γ-rays; charged particle rays such as electron beams and α-rays; and the like. The acid generator (B) may be contained in the photoresist composition (A) either in the form of a compound described later (hereinafter, may be also referred to as “(B) acid generating agent” or “acid generating agent (B)”, as appropriate) or in the form incorporated as a part of the polymer, or may be in both of these forms.

The acid generating agent (B) is exemplified by an onium salt compound, an N-sulfonyloxyimide compound, a halogen-containing compound, a diazo ketone compound, and the like.

The onium salt compound is exemplified by a sulfonium salt, a tetrahydrothiophenium salt, an iodonium salt, a phosphonium salt, a diazonium salt, a pyridinium salt, and the like.

Examples of the sulfonium salt include triphenylsulfonium trifluoromethanesulfonate, triphenylsulfonium nonafluoro-n-butanesulfonate, triphenylsulfonium perfluoro-n-octanesulfonate, triphenylsulfonium 2-bicyclo[2.2.1]hept-2-yl-1,1,2,2-tetrafluoroethanesulfonate, triphenylsulfonium 1,1,2,2-tetrafluoro-6-(1-adamantanecarbonyloxy)-hexane-1-sulfonate, triphenylsulfonium 2-(1-adamantyl)-1,1-difluoroethanesulfonate, triphenylsulfonium camphorsulfonate, 4-cyclohexylphenyldiphenylsulfonium trifluoromethanesulfonate, 4-cyclohexylphenyldiphenylsulfonium nonafluoro-n-butanesulfonate, 4-cyclohexylphenyldiphenylsulfonium perfluoro-n-octanesulfonate, 4-cyclohexylphenyldiphenylsulfonium 2-bicyclo[2.2.1 ]hept-2-yl-1,1,2,2-tetrafluoroethanesulfonate, 4-cyclohexylphenyldiphenylsulfonium camphorsulfonate, 4-methanesulfonylphenyldiphenylsulfonium trifluoromethanesulfonate, 4-methanesulfonylphenyldiphenylsulfonium nonafluoro-n-butanesulfonate, 4-methanesulfonylphenyldiphenylsulfonium perfluoro-n-octanesulfonate, 4-methanesulfonylphenyldiphenylsulfonium 2-bicyclo[2.2.1]hept-2-yl-1,1,2,2-tetrafluoroethanesulfonate, 4-methanesulfonylphenyldiphenylsulfonium camphorsulfonate, 2,4,6-trimethylphenyldiphenylsulfonium 2,4-difluorobenzenesulfonate, and the like.

Examples of the tetrahydrothiophenium salt include 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate, 1-(4-n-butoxynaphthalen-1-yl)tetrahydrothiophenium 2-bicyclo[2.2.1]hept-2-yl-1,1,2,2-tetrafluoroethane sulfonate, 1-(4-n-butoxynaphthalen-1-yl)tetrahydrothiophenium camphorsulfonate, 1-(6-n-butoxynaphthalen-2-yl)tetrahydrothiophenium trifluoromethanesulfonate, 1-(6-n-butoxynaphthalen-2-yl)tetrahydrothiophenium nonafluoro-n-butanesulfonate, 1-(6-n-butoxynaphthalen-2-yl)tetrahydrothiophenium perfluoro-n-octanesulfonate, 1-(6-n-butoxynaphthalen-2-yl)tetrahydrothiophenium 2-bicyclo[2.2.1]hept-2-yl-1,1,2,2-tetrafluoroethanesulfonate, 1-(6-n-butoxynaphthalen-2-yl)tetrahydrothiophenium camphorsulfonate, 1-(3,5-dimethyl-4-hydroxyphenyl)tetrahydrothiophenium trifluoromethanesulfonate, 1-(3,5-dimethyl-4-hydroxyphenyl)tetrahydrothiophenium nonafluoro-n-butanesulfonate, 1-(3,5-dimethyl-4-hydroxyphenyl)tetrahydrothiophenium perfluoro-n-octanesulfonate, 1-(3,5-dimethyl-4-hydroxyphenyl)tetrahydrothiophenium 2-bicyclo[2.2.1]hept-2-yl-1,1,2,2-tetrafluoroethanesulfonate, 1-(3,5-dimethyl-4-hydroxyphenyl)tetrahydrothiophenium camphorsulfonate, and the like.

Examples of the iodonium salt include diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, diphenyliodonium camphorsulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, bis(4-t-butylphenyl)iodonium 2-bicyclo[2.2.1]hept-2-yl-1,1,2,2-tetrafluoroethanesulfonate, bis(4-t-butylphenyl)iodonium camphorsulfonate, and the like.

Examples of the N-sulfonyloxyimide compound include N-(trifluoromethanesulfonyloxy)bicyclo[2.2.1]hept-5-ene-2,3-dicarboxyimide, N-(nonafluoro-n-butanesulfonyloxy)bicyclo[2.2.1]hept-5-ene-2,3-dicarboxyimide, N-(perfluoro-n-octanesulfonyloxy)bicyclo[2.2.1]hept-5-ene-2,3-dicarboxyimide, N-(2-bicyclo[2.2.1]hept-2-yl-1,1,2,2-tetrafluoroethanesulfonyloxy)bicyclo[2.2.1]hept-5-ene-2,3-dicarboxyimide, N-(2-(3-tetracyclo[4.4.0.1^{2,5}.1^{7,10}]dodecanyl)-1,1-difluoroethanesulfonyloxy)bicyclo[2.2.1]hept-5-ene-2,3-dicarboxyimide, N-(camphorsulfonyloxy)bicyclo[2.2.1]hept-5-ene-2,3-dicarboxyimide, and the like.

Of these, onium salt compounds and N-sulfonyloxyimide compounds are preferred, sulfonium salts, tetrahydrothiophenium salts and N-sulfonyloxyimide compound are more preferred, sulfonium salts containing a fluorinated benzenesulfonate anion, tetrahydrothiophenium salts containing a fluorinated alkylsulfonate anion, and N-sulfonyloxyimide compounds that include a fluorinated alkyl group are still more preferred, and 2,4,6-trimethylphenyldiphenylsulfonium 2,4-difluorobenzenesulfonate, 1-(4-n-butoxynaphthalen-1-yl)tetrahydrothiophenium nonafluoro-n-butanesulfonate, and N-(trifluoromethanesulfonyloxy)bicyclo[2.2.1]hept-5-ene-2,3-dicarboxyimide are particularly preferred.

These the acid generators (B) may be used either alone, or as a mixture of two or more types thereof.

In a case where the acid generator (B) is the acid generating agent, in light of an improvement of the sensitivity and developability of the photoresist (A), the content of the acid generator (B) is typically 0.1 parts by mass to 30 parts by mass, preferably 0.2 parts by mass to 20 parts by mass, more preferably 0.3 parts by mass to 15 parts by mass, still more preferably 0.5 parts by mass to 10 parts by mass, and particularly preferably 1 part by mass to 5 parts by mass with respect to 100 parts by mass of the polymer (A). When the content of the acid generating agent (B) is less than the lower limit, the sensitivity of the photoresist composition (A) and the developability of the formed resist film may be deteriorated. When the content of the acid generating agent (B) is greater than the upper limit, the transparency to the exposure light may be impaired, and consequently obtaining a desired resist pattern may be difficult.

### (C) Compound

The compound (C) includes at least one (hereinafter, may be also referred to as “group (C)”) selected from the group consisting of a carboxy group, a sulfo group, a group (a) represented by the above formula (i), a group capable of generating the carboxy group, the sulfo group or the group (a) by the action of an acid, and a lactonic carbonyloxy group, and has a molecular weight of no greater than 1,000. The compound (C) includes the above-specified acidic group, the group capable of generating the acidic group by the action of an acid generated from the acid generator (B) upon an exposure, and/or a lactone ring. It is presumed that at the light-exposed site, the compound (C) can inhibit permeation of the organic solvent-containing developer solution into the resist film, leading to an effective improvement of the adhesiveness of the resist film to the substrate, whereas at the light-unexposed site, the compound (C) can improve the solubility of the resist film in the organic solvent-containing developer solution. Consequently, the peeling of the pattern and the generation of scums in the resist pattern thus formed can be further inhibited and, in turn, the accuracy of the ion implantation in the method for producing a semiconductor element and the ion implantation method can be improved.

The compound (C) is not particularly limited as long as it includes the group (C), and is exemplified by a hydrocarbon in which a part or all of hydrogen atoms thereof are substituted with the group (C), and the like.

The hydrocarbon is exemplified by a chain hydrocarbon, an alicyclic hydrocarbon, an aromatic hydrocarbon, and the like.

Examples of the chain hydrocarbon include:

alkanes such as methane, ethane, propane, linear or branched butane, linear or branched pentane, linear or branched hexane, linear or branched heptane, linear or branched octane, linear or branched nonane and linear or branched decane;

alkenes such as ethene, propene, linear or branched butene, linear or branched pentene, linear or branched hexene, linear or branched heptene, linear or branched octene, linear or branched nonene and linear or branched decene;

alkenes such as ethyne, propyne, linear or branched butyne, linear or branched pentyne, linear or branched hexyne, linear or branched heptyne, linear or branched octyne, linear or branched nonyne and linear or branched decyne; and the like.

Examples of the alicyclic hydrocarbon include:

monocyclic cycloalkanes such as cyclopropane, cyclobutane, cyclopentane, cyclohexane, cycloheptane, cyclooctane, cyclononane and cyclodecane;

polycyclic cycloalkanes, e.g.: bridged hydrocarbons such as norbornane, methylnorbornane, adamantane, tricyclodecane and tetracyclododecane; steroid ring-containing hydrocarbons such as cholestane, cholane, pregnane, homopregnane, androstane and estrane;

monocyclic cycloalkenes such as cyclopropene, cyclobutene, cyclopentene, cyclohexene, cycloheptene, cyclooctene, cyclononene and cyclodecene;

polycyclic cycloalkenes such as norbornene, tricyclodecene and tetracyclododecene; and the like.

Examples of the aromatic hydrocarbon include benzene, toluene, xylene, mesitylene, hexamethylbenzene, cyclohexylbenzene, naphthalene, anthracene, and the like.

Of these, in light of further inhibiting the peeling of the pattern and the generation of scums in the resist pattern formed in the method for producing a semiconductor element and the ion implantation method, alicyclic hydrocarbons are preferred, polycyclic cycloalkanes are more preferred, bridged hydrocarbons and steroid ring-containing hydrocarbons are still more preferably, and adamantane, norbornane and cholane are particularly preferred.

The “lactonic carbonyloxy group” as referred to means a divalent group which is represented by —COO— and links two carbon atoms of a single molecule to form a lactone ring. Examples of the compound (C) that includes a lactonic carbonyloxy group include: monocyclic lactones such as butyrolactone, valerolactone and caprolactone; polycyclic lactones such as norbornanelactone, 7-oxanorbornanelactone and 5-oxo-4-oxatricyclo[4.3.1.1^{3,8}]undecane; and the like.

In the above formula (i), Rf¹ and Rf² each independently represent a hydrogen atom, a fluorine atom or a perfluoroalkyl group; and k is an integer of 1 to 5, wherein in a case where k is no less than 2, a plurality of Rf¹s may be each identical or different, and a plurality of Rf²s may be each identical or different, wherein at least one of Rf¹ and Rf² bonding to the carbon atom adjacent to the hydroxy group does not represent a hydrogen atom.

Examples of the perfluoroalkyl group which may be represented by Rf¹ and Rf² include a trifluoromethyl group, a pentafluoroethyl group, a heptafluoro-n-propyl group, a heptafluoro-i-propyl group, a nonafluoro-n-butyl group, a nonafluoro-i-butyl group, a nonafluoro-sec-butyl group, a nonafluoro-t-butyl group, and the like.

Rf¹ and Rf² represent preferably a fluorine atom or a perfluoroalkyl group, more preferably a perfluoroalkyl group, and still more preferably a trifluoromethyl group.

Preferably, k is an integer of 1 to 3, more preferably 1 or 2, and still more preferably 1.

Examples of the group (a) include a hydroxy-bis(trifluoromethyl)methyl group, a hydroxy-trifluoromethylmethyl group, a hydroxy-difluoromethyl group, a hydroxy-fluoromethyl group, a hydroxy-trifluoromethyl-fluoromethyl group, a hydroxy-bis(pentafluoroethyl)methyl group, a hydroxy-trifluoromethyl-pentafluoroethylmethyl group, a hydroxy-pentafluoroethyl-fluoromethyl group, a 2-hydroxy-1,1,2,2-tetrafluoroethyl group, a 2-hydroxy-1,2,2,-trifluoroethyl group, a 3-hydroxy-1,1,2,2,3,3-hexafluoropropyl group, and the like. Of these, a hydroxy-bis(trifluoromethyl)methyl group is preferred.

Examples of the group capable of generating the carboxy group, the sulfo group or the group (a) by the action of an acid include groups obtained from the carboxy group, the sulfo group or the group (a) by substituting a hydrogen atom included therein with an acid-labile group, and the like. The “acid-labile group” as referred to is as defined in connection with the acid-labile group included in the structural unit (I) of the polymer (A), and means a group that substitutes for a hydrogen atom of an acidic group such as a carboxy group, a sulfo group or the group (a) and is dissociated by the action of an acid.

Examples of the group capable of generating a carboxy group by the action of an acid include groups obtained by substituting the hydrogen atom of a carboxy group with an acid-labile group, and the like. The acid-labile group is exemplified by a hydrocarbon group having a binding site on a tertiary carbon atom, and the like, and specific examples thereof include:

monovalent acid-labile groups such as a t-butyl group, a t-pentyl group, a t-hexyl group, a t-heptyl group, a t-octyl group, a t-decyl group, a 1,1,2,2-tetramethylpropyl group, a 1-methylcyclopentyl group, a 1-ethylcyclopentyl group, a 1-methylcyclohexyl group, a 1-ethylcyclohexyl group, a 1-methylcyclooctyl group and a 1-ethylcyclooctyl group;

divalent acid-labile groups such as a 2,3-dimethylbutane-2,3-diyl group, a 2,4-dimethylpentane-2,4-diyl group, a 2,5-dimethylhexane-2,5-diyl group, a 1,3-dimethylcyclopentane-1,3-diyl group, a 1,3-diethylcyclopentane-1,3-diyl group, a 1,3-dimethylcyclohexane-1,3-diyl group and a 1,4-dimethylcyclohexane-1,4-diyl;

acid-labile groups having a valency of no less than 3, such as a 2,4,6-trimethylheptane-2,4,6-triyl group, a 1,3,5-trimethylcyclohexane-1,3,5-triyl group, a 1,3,5,7-tetraethylcyclooctane-1,3,5,7-tetrayl group; and the like.

Moreover, the acid-labile group is also exemplified by a group having an alkoxy group bound to a carbon atom serving as a binding site. Specific examples of such a group include: monovalent acid-labile groups such as a methoxymethyl group and an ethoxymethyl group; divalent acid-labile groups such as a methanediyloxymethanediyl group and a (bis(methanediyloxy)methyl group; trivalent acid-labile groups such as a tris(methanediyloxy)methyl group and a tris(methanediyloxy)ethyl group; and the like.

Examples of the group capable of generating a sulfo group by the action of an acid include group obtained from a sulfo group by substituting a hydrogen atom thereof with an acid-labile group, and the like. Examples of the acid-labile group include acid-labile groups similar to those exemplified in connection with the group capable of generating the carboxy group, and the like.

Examples of the group capable of generating the group (a) by the action of an acid include groups obtained from the group (a) by substituting a hydrogen atom thereof with an acid-labile group, and the like. Examples of this acid-labile group include acid-labile groups similar to those exemplified in connection with the group capable of generating the carboxy group, and the like.

The number of the carboxy group, the sulfo group, the group (a), the group capable of generating the carboxy group, the sulfo group or the group (a) by the action of an acid, and the lactonic carbonyloxy group included in the compound (C) is not particularly limited, and either one type of such groups, or two or more types thereof may be included.

The compound (C) may include, in addition to the group (C) described above, e.g. a halogen atom such as a fluorine atom, a chlorine atom, a bromine atom and an iodine atom, a hydroxy group, a cyano group, a nitro group, a oxo group (═O), an alkoxy group, an alkoxycarbonyl group, an alkoxycarbonyloxy group, an acyl group, an acyloxy group, and/or the like.

The compound (C) preferably has an alicyclic skeleton, and more preferably at least one type of skeleton selected from the group consisting of an adamantane skeleton, a norbornane skeleton and a steroid skeleton. When the compound (C) has an alicyclic skeleton, the inhibition of the permeation of the organic solvent-containing developer solution into the resist film and the adhesiveness of the resist film to the substrate can be enhanced at the light-exposed site, and the solubility of the resist film in the organic solvent-containing developer solution can be improved at the light-unexposed site. Consequently, the peeling of the pattern and the generation of scums in the resist pattern formed in the method for producing a semiconductor element and the ion implantation method can be further inhibited. The alicyclic skeleton may be included in the hydrocarbon, for example, or in the group (a) or the like.

The upper limit of the molecular weight of the compound (C) is 1,000, preferably 800, more preferably 600, and still more preferably 500. On the other hand, the lower limit of the molecular weight of the compound (C) is preferably 50, more preferably 100, and still more preferably 150. When the molecular weight of the compound (C) falls within the above-specified range, the dispersibility thereof in the resist film can be improved, and consequently, the peeling of the pattern and the generation of scums in the resist pattern formed according to the method for producing a semiconductor element and the ion implantation method can be further inhibited.

Examples of the preferred compound (C) include compounds represented by the above formulae (1), (2-1), (2-2) and (3).

In the above formula (1), R¹ represents a hydrogen atom or an acid-labile group having a valency of m; R² represents a hydrogen atom or a monovalent acid-labile group; m is an integer of 1 to 4; and n is an integer of 0 to 15, wherein in a case where R² is present in a plurality of number, a plurality of R²s may be each identical or different.

In the above formulae (2-1) and (2-2), R³ and R^{3′} each independently represent a hydrogen atom, an alkyl group having 1 to 5 carbon atoms or a monovalent acid-labile group; R⁴ and R^{4′} each independently represent a hydroxy group, an alkoxy group or the group (a); p is an integer of 0 to 10; q is an integer of 0 to 10; p′ is an integer of 0 to 12; q′ is an integer of 0 to 12, wherein the sum of p and q is no less than zero and no greater than 10, the sum of p′ and q′ is no less than 1 and no greater than 12, wherein in a case where R³, R^{3′}, R⁴ and R^{4′} are each present in a plurality of number, a plurality of R³s may be each identical or different, a plurality of R^{3′}s may be each identical or different, a plurality of R⁴s may be each identical or different and a plurality of R^{4′}s may be each identical or different, and wherein at least one of R^{3′} and R^{4′} represents a hydrogen atom, a monovalent acid-labile group or the group (a).

In the above formula (3), R⁵ represents a hydrogen atom, a monovalent acid-labile group, or a monovalent organic group including an acid-labile group; R⁶, R⁷ and R⁸ each independently represent a hydrogen atom, —OH or ═O; and r is 1 or 2.

The compounds represented by the above formulae (1), (2-1), (2-2) and (3) include a polycyclic alicyclic structure. More specifically, the compound represented by the above formula (1) includes an adamantane structure, the compounds represented by the above formulae (2-1) and (2-2) include a norbornane structure, and the compound represented by the above formula (3) includes a steroid ring structure.

The acid-labile group having a valency of m (a valency of 1 to 4) which may be represented by R¹ and the monovalent acid-labile group which may be represented by R² are exemplified by the acid-labile group included in the aforementioned group capable of generating a carboxy group by the action of an acid. Preferably, m is 1 or 2, and more preferably 1, and n is preferably an integer of 0 to 2, and more preferably 0 or 1. R¹ preferably represents a hydrogen atom or a monovalent acid-labile group.

Examples of the alkyl group having 1 to 5 carbon atoms which may be represented by R³ or R^{3′} include a methyl group, an ethyl group, a n-propyl group, an i-propyl group, a n-butyl group, an i-butyl group, a sec-butyl group, a t-butyl group, a n-pentyl group, an i-pentyl group, a sec-pentyl group, a t-pentyl group, and the like. Of these, a methyl group is preferred.

The monovalent acid-labile group which may be represented by R³ or R^{3′} is exemplified by monovalent acid-labile groups similar to those exemplified in connection with R², and the like.

R³ and R^{3′} preferably represent a hydrogen atom or a monovalent acid-labile group. Preferably, p and p′ are an integer of 0 to 2, more preferably 0 or 1, and still more preferably 0.

Examples of the alkoxy group which may be represented by R⁴ or R^{4′} include a methoxy group, an ethoxy group, a n-propoxy group, an i-propoxy group, a n-butoxy group, an i-butoxy group, a sec-butoxy group, a t-butoxy group, a n-pentyloxy group, an i-pentyloxy group, a sec-pentyloxy group, a t-pentyloxy group, and the like. Of these, an alkoxy group having 1 to 8 carbon atoms is preferred, an alkoxy group having 1 to 4 carbon atoms is more preferred, and a methoxy group is still more preferred.

Examples of the group (a) which may be represented by R⁴ or R^{4′} include groups similar to those exemplified in connection with the group (a), and the like.

R⁴ and R^{4′} preferably represent a hydroxy group or the group (a). Preferably, q and q′ are an integer of 0 to 2, more preferably 0 or 1, and still more preferably 1.

Examples of the monovalent acid-labile group which may be represented by R⁵ include monovalent acid-labile groups similar to those exemplified in connection with R², and the like. Moreover, examples of the monovalent organic group including an acid-labile group which may be represented by R⁵ include: alkanediyl groups having 1 to 10 carbon atoms and having a carboxy group whose hydrogen atom is substituted with an acid-labile group; cycloalkanediyl groups having 3 to 10 carbon atoms and having a carboxy group whose hydrogen atom is substituted with an acid-labile group; divalent aromatic groups having 6 to 20 carbon atoms and having a carboxy group whose hydrogen atom is substituted with an acid-labile group; and the like. A part or all of hydrogen atoms included in the alkanediyl group, the cycloalkanediyl group and the aromatic group may be unsubstituted or substituted.

Specific examples of the preferred compound represented by the above formula (1) include compounds represented by the following formulae.

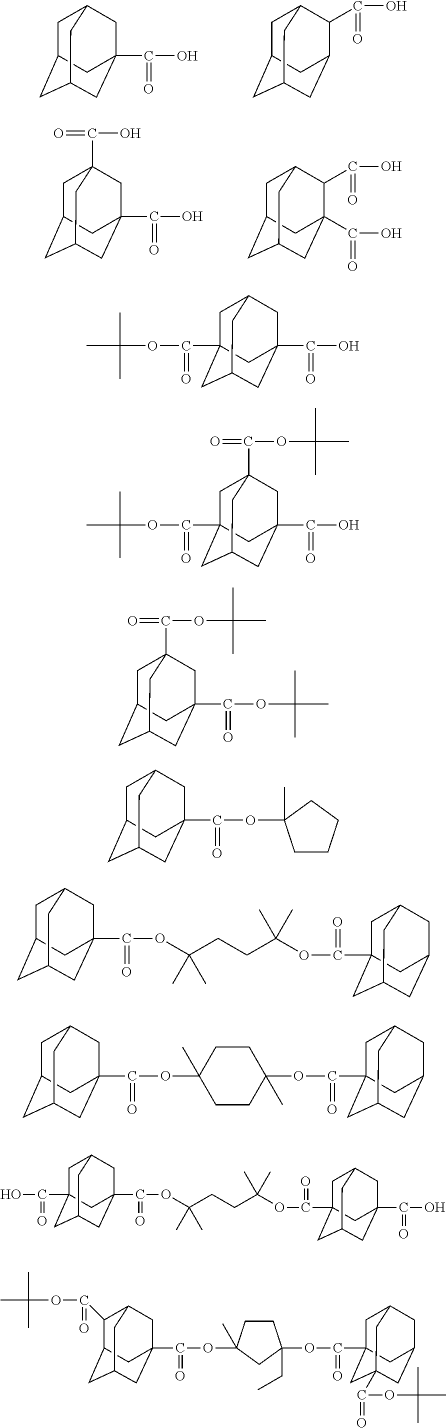

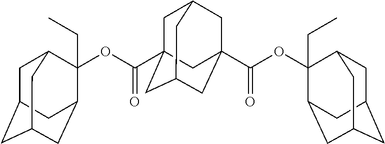 [SMILES: CCC1(OC(=O)C23CC4CC(C2)CC(C(=O)OC2(CC)C5CC6CC(C5)CC2C6)(C4)C3)C2CC3CC(C2)CC1C3]

Of these, in light of further inhibiting the peeling of the pattern and the generation of scums in the resist pattern formed according to the method for producing a semiconductor element and the ion implantation method, compounds that include 1 or 2 carboxy group(s) and compounds that include 1 or 2 group(s) capable of generating a carboxy group by the action of an acid are preferred, and 1-adamantanecarboxylic acid and 1,3-bis(2-ethyladamantan-2-yloxycarbonyl)adamantane are more preferred.

Specific examples of the preferred compound represented by the above formula (2-1) include compounds represented by the following formulae.

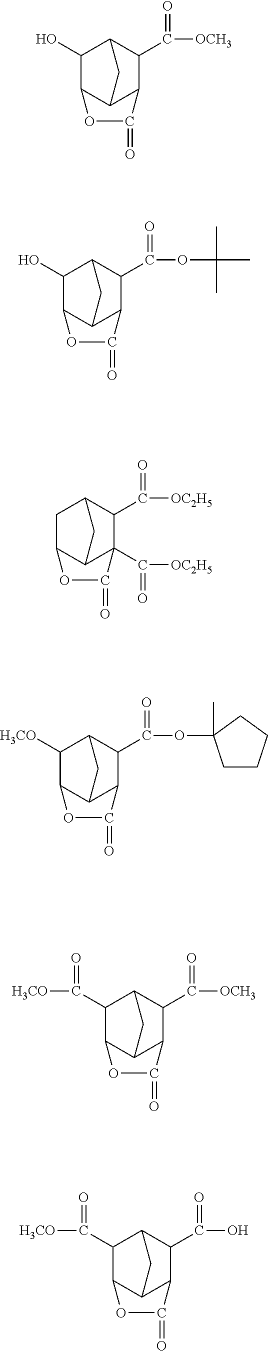 [SMILES: COC(=O)C1C2CC3C(OC(=O)C31)C2O ; CC(C)(C)OC(=O)C1C2CC3C(OC(=O)C31)C2O ; CCOC(=O)C1C2CC3OC(=O)C1(C(=O)OCC)C3C2 ; COC1C2CC3C1OC(=O)C3C2C(=O)OC1(C)CCCC1 ; COC(=O)C1C2CC3C1OC(=O)C3C2C(=O)OC ; COC(=O)C1C2CC3C1OC(=O)C3C2C(=O)O]

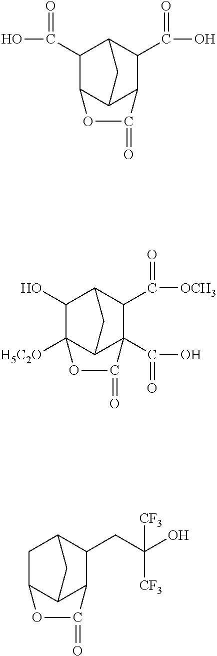

Of these, in light of further inhibiting the peeling of the pattern and the generation of scums in the resist pattern formed according to the method for producing a semiconductor element and the ion implantation method, compounds that include a hydroxy group are preferred, compounds that include one hydroxy group are more preferred, and 2-hydroxy-6-methoxycarbonylnorbornanelactone is still more preferred.

Specific examples of the preferred compound represented by the above formula (2-2) include compounds represented by the following formulae.

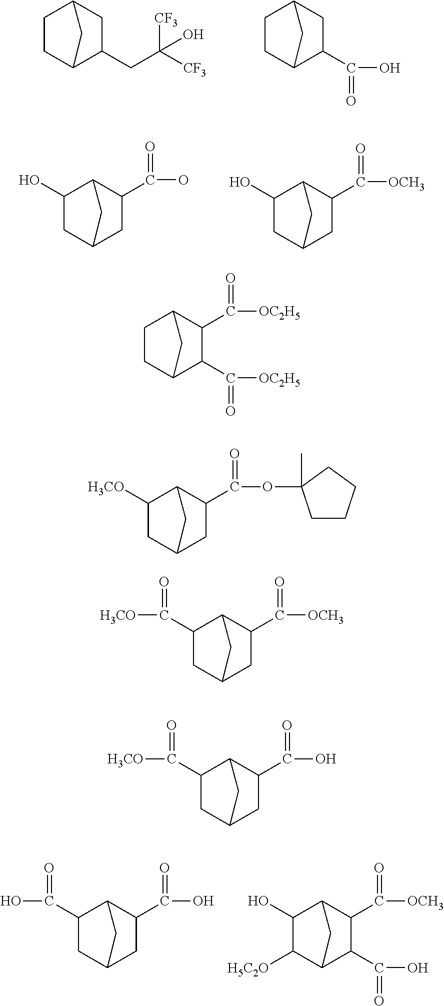

Of these, in light of further inhibiting the peeling of the pattern and the generation of scums in the resist pattern formed according to the method for producing a semiconductor element and the ion implantation method, compounds that include the group (a) is preferred, compounds that include a 2-hydroxy-bis(perfluoroalkyl)methyl group are more preferred, and 243,3,3-trifluoro-2-trifluoromethyl-2-hydroxypropyl)norbornane is still more preferred.

Preferred specific examples of the compound represented by the above formula (3) include compounds represented by the following formulae.

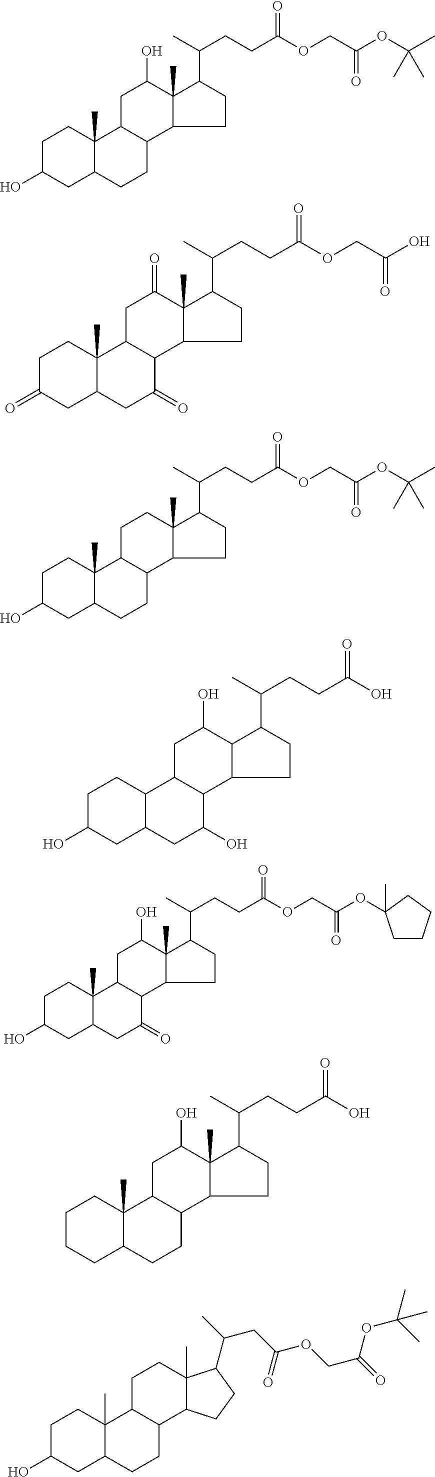

Of these, in light of further inhibiting the peeling of the pattern and the generation of scums in the resist pattern formed according to the method for producing a semiconductor element and the ion implantation method, compounds including a hydroxy group are preferred, compounds including one or two hydroxy group(s) are more preferred, t-butoxycarbonylmethyl 3-hydroxycholanate, t-butoxycarbonylmethyl 3-hydroxy-23-norcholanate, t-butoxycarbonylmethyl 3,12-dihydroxycholanate are still more preferred, and t-butoxycarbonylmethyl 3-hydroxy-23-norcholanate is particularly preferred.

In the photoresist composition (A), the lower limit of the content of the compound (C) is 0.1 parts by mass, preferably 0.5 parts by mass, more preferably 1 part by mass, still more preferably 2 parts by mass, and particularly preferably 3 parts by mass with respect to 100 parts by mass of the polymer (A). On the other hand, the upper limit of the content of the compound (C) is 30 parts by mass, preferably 20 parts by mass, more preferably 15 parts by mass, still more preferably 10 parts by mass, and particularly preferably 7 parts by mass. When the content of the compound (C) is less than the lower limit, the inhibitory effect on the peeling of the pattern and the generation of scums in the resist pattern formed in the method for producing a semiconductor element and the ion implantation method tends to be deteriorated. To the contrary, when the content of the compound (C) is greater than the upper limit, the configuration of the resist pattern in the method for producing a semiconductor element and the ion implantation method may be deteriorated.

### (D) Acid Diffusion Controller

The acid diffusion controller (D) exerts the effect of controlling a diffusion phenomenon of the acid generated from the acid generator (B) upon an exposure in the resist coating film, and inhibiting unfavorable chemical reactions in an unexposed region; as a result, the storage stability of the resulting photoresist composition is further improved, and a resolution thereof for use as a resist is further improved, while variation of line width of the resist pattern caused by variation of post-exposure time delay from the exposure until a development treatment can be suppressed, which enables the composition with superior process stability to be obtained. The acid diffusion controller may be contained in the composition either in the form of a free compound (hereinafter, may be also referred to as “(D) acid diffusion control agent” or “acid diffusion control agent (D)”, as appropriate) or in the form incorporated as a part of the polymer, or may be in both of these forms.

The acid diffusion control agent (D) is exemplified by an amine compound, an amide group-containing compound, a urea compound, a nitrogen-containing heterocyclic compound, and the like.

Examples of the amine compound include: mono(cyclo)alkylamines; di(cyclo)alkylamines; tri(cyclo)alkylamines; substituted alkylaniline or derivatives thereof; ethylenediamine, N,N,N′,N′-tetramethylethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, 2,2-bis(4-aminophenyl)propane, 2-(3-aminophenyl)-2-(4-aminophenyl)propane, 2-(4-aminophenyl)-2-(3-hydroxyphenyl)propane, 2-(4-aminophenyl)-2-(4-hydroxyphenyl)propane, 1,4-bis(1-(4-aminophenyl)-1-methylethyl)benzene, 1,3-bis(1-(4-aminophenyl)-1-methylethyl)benzene, bis(2-dimethylaminoethyl)ether, bis(2-diethylaminoethyl)ether, 1-(2-hydroxyethyl)-2-imidazolidinone, 2-quinoxalinol, N,N,N′,N′-tetrakis(2-hydroxypropyl)ethylenediamine, N,N,N′,N″N″-pentamethyldiethylenetriamine; and the like.

Examples of the amide group-containing compound include N-t-butoxycarbonyl group-containing amino compounds, formamide, N-methylformamide, N,N-dimethylformamide, acetamide, N-methylacetamide, N,N-dimethylacetamide, propionamide, benzamide, pyrrolidone, N-methylpyrrolidone, N-acetyl-1-adamantylamine, tris(2-hydroxyethyl)isocyanurate, and the like.

Examples of the urea compound include urea, methylurea, 1,1-dimethylurea, 1,3-dimethylurea, 1,1,3,3-tetramethylurea, 1,3-diphenylurea, tri-n-butylthiourea, and the like.

Examples of the nitrogen-containing heterocyclic compound include: imidazoles such as 2-phenylbenzimidazole; pyridines; piperazines; pyrazine, pyrazole, pyridazine, quinoxaline, purine, pyrrolidine, piperidine, piperidineethanol, 3-piperidino-1,2-propanediol, morpholine, 4-methylmorpholine, 1-(4-morpholinyl)ethanol, 4-acetylmorpholine, 3-(N-morpholino)-1,2-propanediol, 1,4-dimethylpiperazine, 1,4-diazabicyclo[2.2.2]octane; and the like.

A nitrogen-containing organic compound that includes an acid-labile group may also be used as the acid diffusion control agent (D). Examples of the nitrogen-containing organic compound that includes an acid-labile group include N-(t-butoxycarbonyl)piperidine, N-(t-butoxycarbonyl)-4-pyrrolidine, N-(t-butoxycarbonyl)imidazole, N-(t-butoxycarbonyl)benzimidazole, N-(t-butoxycarbonyl)-2-phenylbenzimidazole, N-(t-butoxycarbonyl)di-n-octylamine, N-(t-butoxycarbonyl)diethanolamine, N-(t-butoxycarbonyl)dicyclohexylamine, N-(t-butoxycarbonyl)diphenylamine, N-(t-butoxycarbonyl)-4-hydroxypiperidine, N-(t-amyloxycarbonyl)-4-hydroxypiperidine, and the like.

Of these, a nitrogen-containing heterocyclic compound, and a nitrogen-containing organic compound that includes an acid-labile group are preferred, imidazoles, N-(t-alkoxycarbonyl)dicyclohexylamine and N-(t-alkoxycarbonyl)-4-hydroxypiperidine are more preferred, and 2-phenylbenzimidazole, N-(t-butoxycarbonyl)dicyclohexylamine and N-(t-amyloxycarbonyl)-4-hydroxypiperidine are still more preferred.

In addition, a photodegradable base which is sensitized upon an exposure to generate a weak acid can be used as the acid diffusion control agent (D). The photodegradable base is exemplified by an onium salt compound and the like that loses acid diffusion controllability through degradation upon an exposure. Examples of the onium salt compound include a sulfonium salt compound represented by the following formula (D1), and an iodonium salt compound represented by the following formula (D2).

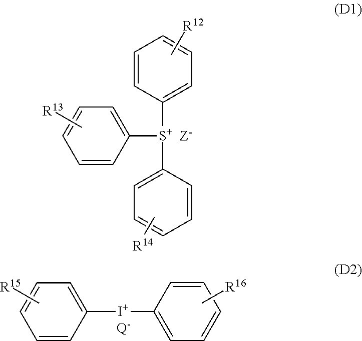

In the above formulae (D1) and (D2), R¹² to R¹⁶ each independently represent a hydrogen atom, an alkyl group, an alkoxyl group, a hydroxy group or a halogen atom; Z⁻ and Q⁻ each independently represent OH⁻, R^{α}—COO⁻ or R^{α}—SO₃⁻, wherein R^{α} represents an alkyl group, an aryl group, an aralkyl group or an anion represented by the following formula (D3).

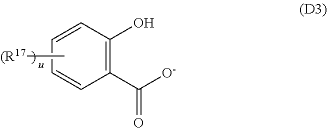

In the above formula (D3), R¹⁷ represents a linear or branched alkyl group having 1 to 12 carbon atoms, or a linear or branched alkoxy group having 1 to 12 carbon atoms, wherein a part or all of hydrogen atoms included in the linear or branched alkyl group or the linear or branched alkoxyl group may be substituted with a fluorine atom; and u is an integer of 0 to 2.

In the case of the acid diffusion controller (D) being (D) an acid diffusion control agent, the content of the acid diffusion controller (D) is preferably 0 parts by mass to 20 parts by mass, more preferably 0.01 parts by mass to 10 parts by mass, still more preferably 0.05 parts by mass to 5 parts by mass, and particularly preferably 0.1 parts by mass to 2 parts by mass with respect to 100 parts by mass of the polymer (A). When the content of the acid diffusion control agent (D) is greater than the upper limit, the sensitivity of the photoresist composition (A) may be deteriorated. The acid diffusion control agent (D) may be used either alone, or as a mixture of two or more thereof.

### (E) Solvent

The photoresist composition (A) typically contains (E) a solvent. The solvent (E) is not particularly limited as long as it is capable of dissolving or dispersing at least the polymer (A), the acid generator (B) and the compound (C) as well as other component contained as needed. The solvent (E) is exemplified by organic solvents similar to those for use in the aforementioned negative resist pattern-forming step of the method for producing a semiconductor element and the ion implantation method, and the like. Of these, ester solvents and ketone solvents are preferred, polyhydric alcohol partial ether acetate solvents, lactone solvents and cyclic ketone solvents are more preferred, and propylene glycol monomethyl ether acetate, γ-butyrolactone and cyclohexanone are still more preferred. The solvent (E) may be used either alone, or as a mixture of two or more thereof.

### Other Component

The photoresist composition (A) may contain, as other component, a fluorine atom-containing polymer, a surfactant, an alicyclic skeleton-containing compound, a sensitizing agent, and the like.

Fluorine Atom-Containing Polymer

The photoresist composition (A) may contain the fluorine atom-containing polymer (except for those corresponding to the polymer (A)). When the photoresist composition (A) contains the fluorine atom-containing polymer, in forming the resist coating film, the fluorine atom-containing polymer tends to be unevenly distributed on the surface layer of the resist coating film due to oil repellent characteristics of the fluorine atom-containing polymer. Consequently, when liquid immersion lithography is executed, elution of the acid generating agent, the acid diffusion control agent and/or the like present in the film into a liquid immersion medium can be inhibited. In addition, due to water repellent characteristics of the fluorine atom-containing polymer, an advancing contact angle of a liquid immersion medium on the resist coating film can be controlled to fall within a desired range, whereby formation of bubble defects can be inhibited. Furthermore, a larger receding contact angle of the liquid immersion medium on the resist coating film can be attained, whereby enabling an exposure by high-speed scanning without being accompanied by residual water beads. Thus, when the photoresist composition (A) contains the fluorine atom-containing polymer, a resist coating film suitable for liquid immersion lithography process can be provided.

The fluorine atom-containing polymer is not particularly limited as long as the polymer contains one or more fluorine atoms, and the fluorine atom-containing polymer can typically be formed by polymerizing one or more types of monomer that includes one or more fluorine atoms in the structure thereof. The monomer that includes one or more fluorine atoms in the structure thereof is exemplified by: a monomer that includes one or more fluorine atoms in the main chain thereof; a monomer that includes one or more fluorine atoms in a side chain thereof; and a monomer that includes one or more fluorine atoms in both the main chain and a side chain thereof.

Examples of the monomer that includes one or more fluorine atoms in the main chain thereof include α-fluoroacrylate compounds, α-trifluoromethylacrylate compounds, β-fluoroacrylate compounds, β-trifluoromethylacrylate compounds, α,β-fluoroacrylate compounds, α,β-trifluoromethylacrylate compounds, compounds in which one or more vinylic hydrogen atoms thereof are substituted with a fluorine atom, a trifluoromethyl group or the like, etc.

Examples of the monomer that includes one or more fluorine atoms in a side chain thereof include: alicyclic olefin compounds such as norbornene which include one or more fluorine atoms, fluoroalkyl groups or derivatives thereof as a side chain; ester compounds obtained from acrylic acid or methacrylic acid, and a fluoroalkyl alcohol or a derivative thereof; one or more types of olefins having one or more fluorine atoms, fluoroalkyl groups or derivatives thereof as a side chain (i.e., a moiety excluding a double bond); and the like.

Examples of the monomer that includes one or more fluorine atoms in both the main chain and a side chain thereof include: ester compounds obtained from α-fluoroacrylic acid, β-fluoroacrylic acid, α,β-fluoroacrylic acid, α-trifluoromethylacrylic acid, β-trifluoromethylacrylic acid, α,β-ditrifluoromethylacrylic acid or the like and a fluoroalkyl alcohol or a derivative thereof; compounds which are obtained by substituting one or more vinylic hydrogen atoms with a fluorine atom, a trifluoromethyl group or the like and have one or more fluorine atoms, fluoroalkyl groups or derivatives thereof on a side chain; compounds that are obtained from one or more types of alicyclic olefin compounds by substituting hydrogen atom(s) bonding to a double bond thereof with a fluorine atom, a trifluoromethyl group or the like, and have one or more fluoroalkyl groups or derivatives thereof in a side chain; and the like. It is to be noted that the alicyclic olefin compound as referred to means a compound that includes a double bond as part of its ring.

The fluorine atom-containing polymer may have, in addition to the aforementioned structural unit that includes one or more fluorine atoms in the structure thereof, one or more types of “other structural unit” such as, for example: a structural unit that includes an acid-labile group for the purpose of controlling a rate of dissolution in a developer solution; a structural unit that includes a lactone skeleton or a hydroxyl group, a carboxy group, etc.; a structural unit that includes an alicyclic compound; a structural unit derived from an aromatic compound for the purpose of inhibiting light scattering due to reflection on the substrate; and the like.

Surfactant

The surfactant exerts the effect of improving coating property, striation, developability, and the like. Examples of the surfactant include: nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate and polyethylene glycol distearate; and the like. Examples of the surfactant also include commercially available products such as: KP341 (manufactured by Shin-Etsu Chemical Co., Ltd.), Polyflow No. 75 and Polyflow No. 95 (all manufactured by Kyoeisha Chemical Co., Ltd.), EFTOP EF301, EFTOP EF303 and EFTOP EF352 (all manufactured by Tochem Products Co. Ltd.), Megaface F171 and Megaface F173 (all manufactured by Dainippon Ink and Chemicals, Incorporated), Fluorad FC430 and Fluorad FC431 (all manufactured by Sumitomo 3M Limited), ASAHI GUARD AG710, Surflon S-382, Surflon SC-101, Surflon SC-102, Surflon SC-103, Surflon SC-104, Surflon SC-105 and Surflon SC-106 (all manufactured by Asahi Glass Co., Ltd.); and the like. These surfactant may be used either alone, or two or more types thereof may be used in combination.

Sensitizing Agent

The sensitizing agent exhibits the action of increasing the amount of the acid produced from the acid generator (B), and exerts the effect of increasing “apparent sensitivity” of the composition.

Examples of the sensitizing agent include carbazoles, acetophenones, benzophenones, naphthalenes, phenols, biacetyl, eosin, rose bengal, pyrenes, anthracenes, phenothiazines, and the like. These sensitizing agent may be used either alone, or two or more types thereof may be used in combination.

### Preparation Method of Photoresist Composition

The photoresist composition (A) may be prepared, for example, by mixing the polymer (A), the acid generator (B), the compound (C), the acid diffusion controller (D), other component and the solvent (E) in a certain ratio. The solid content concentration of the photoresist composition (A) is typically 1 part by mass to 50% by mass, preferably 3% by mass to 30% by mass, and more preferably 5% by mass to 25% by mass. It is preferred that after mixing the components, the resulting mixed liquid is filtered through a filter with a pore size of about 0.2 μm, for example.

### EXAMPLES

Hereinafter, the present invention is explained in detail by way of Examples, but the present invention is not in any way limited to these Examples. Measuring methods for various physical properties are shown below.

### ¹³C-NMR Analysis

A ¹³C-NMR analysis of the polymer was carried out using a nuclear magnetic resonance apparatus (JNM-ECX400, manufactured by JEOL, Ltd.) and DMSO-d₆ as a solvent for measurement.

### Synthesis of Polymer (A)

Monomers used in the synthesis of the polymer (A) are shown below.

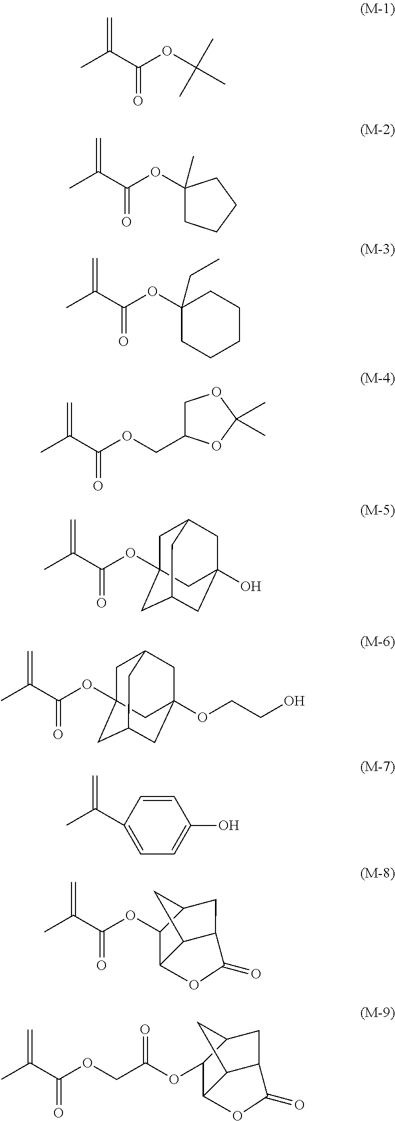

### Synthesis Example 1

### Synthesis of Polymer (A-1)

A monomer solution was prepared by dissolving the compound (M-1) (60 mol %) and the compound (M-8) (40 mol %), and AIBN (5 mol %) as a polymerization initiator in 60 g of methyl ethyl ketone. It is to be noted that the mol % value of each monomer compound is defined as a proportion with respect to the total monomer compounds, and the mol % value of the polymerization initiator was defined as a proportion with respect to the total number of moles of the total monomer compounds and the polymerization initiator. In addition, the total mass of the monomer compounds was adjusted so as to give 30 g.

Separately, 30 g of methyl ethyl ketone was charged into a 500 mL three-neck flask equipped with a thermometer and a dropping funnel, and purging with nitrogen was executed for 30 min. Thereafter, the contents inside the flask were heated so as to reach 80° C. with stirring by means of a magnetic stirrer.

Next, the monomer solution prepared above was added dropwise into the flask over 3 hrs using the dropping funnel. The time of the start of the dropwise addition was regarded as the time of the start of the polymerization reaction, and the polymerization reaction was allowed to proceed for 6 hrs. Thereafter, the reaction mixture was cooled to 30° C. or below to obtain a polymerization solution. This polymerization solution was poured into 600 g of methanol, and a precipitated white powder was filtered off. The collected white powder was washed twice with 120 g of methanol in a slurry, filtered off, and then dried at 50° C. for 17 hrs, whereby a polymer (A-1) was obtained as a white powder (yield: 68%). The result of the ¹³C-NMR analysis indicated that the proportions (mol %) of the structural unit derived from the compound (M-1) and the structural unit derived from the compound (M-8) in the polymer (A-1) was 59:41, respectively. In addition, the polymer (A-1) had an Mw of 7,100 and an Mw/Mn of 1.51.

### Synthesis Examples 2 to 5

### Synthesis of Polymers (A-2) to (A-5)

Polymers (A-2) to (A-5) were each obtained in a similar manner to Synthesis Example 1 except that the type and the amount of each monomer compound used were as specified in Table 1 below. In Table 1, it is to be noted that “-” indicates that the corresponding monomer was not used. The proportions of the structural units derived from the monomer compounds, the Mw, the Mw/Mn and the yield of each polymer obtained are shown together in Table 1.

TABLE 1

| | | Structural unit (I) | | | Structural unit (II) | | | Structural unit (III) | | | | | | |
|---|---|---|---|---|---|---|---|---|---|---|---|---|---|---|
| | | | | proportion | | | proportion | | | proportion | Polymeriza- | | | |
| | | | | of | | | of | | | of | tion | | Physical | |
| | | | monomer | structural | | monomer | structural | | monomer | structural | initiator | | properties | |
| | (A) | | amount | unit | | amount | unit | | amount | unit | amount | Yield | | Mw/ |
| | Polymer | type | (mol %) | (mol %) | type | (mol %) | (mol %) | type | (mol %) | (mol %) | (mol %) | (%) | Mw | Mn |
| Synthesis | A-1 | M-1 | 60 | 59 | M-8 | 40 | 41 | — | — | — | 5 | 68 | 7,100 | 1.51 |
| Example 1 | | | | | | | | | | | | | | |
| Synthesis | A-2 | M-2 | 50 | 50 | M-8 | 50 | 50 | — | — | — | 5 | 72 | 7,500 | 1.50 |
| Example 2 | | | | | | | | | | | | | | |
| Synthesis | A-3 | M-2 | 60 | 60 | — | — | — | M-5 | 40 | 40 | 5 | 70 | 7,800 | 1.49 |
| Example 3 | | | | | | | | | | | | | | |
| Synthesis | A-4 | M-4 | 50 | 49 | M-9 | 40 | 41 | M-7 | 10 | 10 | 5 | 61 | 6,900 | 1.61 |
| Example 4 | | | | | | | | | | | | | | |
| Synthesis | A-5 | M-3 | 50 | 50 | M-8 | 35 | 36 | M-6 | 15 | 14 | 5 | 64 | 6,500 | 1.52 |
| Example 5 | | | | | | | | | | | | | | |

### Preparation of Photoresist Compositions

The acid generating agent (B), the compound (C), the acid diffusion control agent (D) and the solvent (E) which were used in the preparation of the photoresist compositions are shown below.

### (B) Acid Generating Agent

B-1: 2,4,6-trimethylphenyldiphenylsulfonium 2,4-difluorobenzenesulfonate (a compound represented by the following formula (B-1))

B-2: N-(trifluoromethanesulfonyloxy)bicyclo[2.2.1]hept-5-ene-2,3-dicarboxyimide (a compound represented by the following formula (B-2))

B-3: 1-(4-n-butoxynaphthalen-1-yl)tetrahydrothiophenium nonafluoro-n-butanesulfonate (a compound represented by the following formula (B-3))

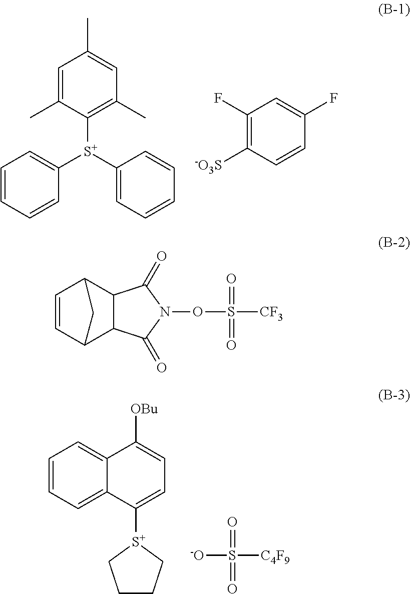

### (C) Compound

C-1: 1-adamantanecarboxylic acid (a compound represented by the following formula (C-1))

C-2: t-butoxycarbonylmethyl 3-hydroxy-23-norcholanate (a compound represented by the following formula (C-2))

C-3: 2-(2-hydroxy-2-trifluoromethyl-3,3,3-trifluoropropyl)norbornane (a compound represented by the following formula (C-3))

C-4: 1,3-bis(2-ethyladamantan-2-yloxycarbonyl)adamantane (a compound represented by the following formula (C-4))

CC-1: adamantane (a compound represented by the following formula (CC-1))

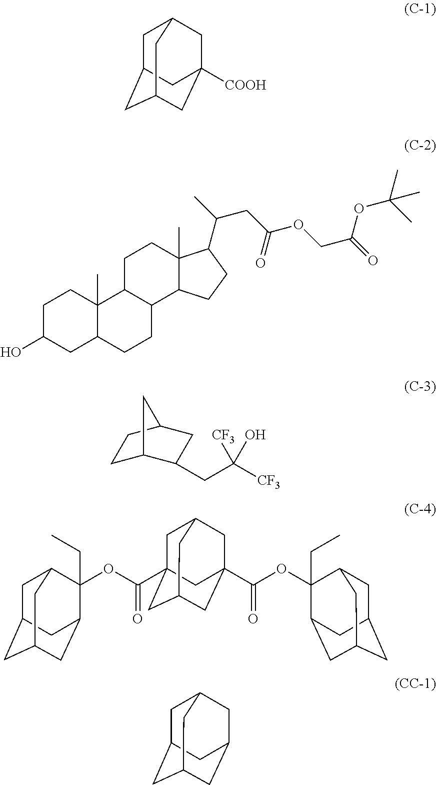

### (D) Acid Diffusion Control Agent

D-1: 2-phenylbenzimidazole (a compound represented by the following formula (D-1))

D-2: N-(t-butoxycarbonyl)dicyclohexylamine (a compound represented by the following formula (D-2))

D-3: N-(t-amyloxycarbonyl)-4-hydroxypiperidine (a compound represented by the following formula (D-3))

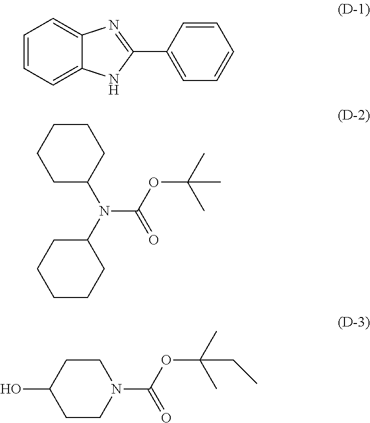

### (E) Solvent

E-1: propylene glycol monomethyl ether acetate

E-2: cyclohexanone

E-3: γ-butyrolactone

### Synthesis Example 6

### Preparation of Photoresist Composition (J-1)

A photoresist composition (J-1) was prepared by mixing 100 parts by mass of (A-1) as the polymer (A), 1.8 parts by mass of (B-1) as the acid generating agent (B), 5 parts by mass of (C-1) as the compound (C), 0.3 parts by mass of (D-1) as the acid diffusion control agent (D), and 385 parts by mass of (E-1), 165 parts by mass of (E-2) and 100 parts by mass of (E-3) as the solvent (E), and filtering the resulting mixed solution through a filter having a pore size of 0.2 μm.

### Synthesis Examples 7 to 15

Photoresist compositions (J-2) to (J-10) were prepared in a similar manner to Synthesis Example 1 except that the type and the amount of each component used were as specified in Table 2 below. In Table 2, it is to be noted that “-” indicates that the corresponding component was not used.

TABLE 2

| | | Formulation | | | | | | | | | |
|---|---|---|---|---|---|---|---|---|---|---|---|
| | | | | (B) acid | | | | (D) acid | | | |
| | | | | generating | | (C) | | diffusion | | | |
| | | (A) polymer | | agent | | compound | | control agent | | | |
| | | | amount | | amount | | amount | | amount | | |
| | | | (parts | | (parts | | (parts | | (parts | (E) solvent | |
| | Photoresist | | by | | by | | by | | by | | amount (parts |
| | composition | type | mass) | type | mass) | type | mass) | type | mass) | type | by mass) |
| Synthesis | J-1 | A-1 | 100 | B-1 | 1.8 | C-1 | 5 | D-1 | 0.3 | E-1/E-2/E-3 | 385/165/100 |
| Example 6 | | | | | | | | | | | |
| Synthesis | J-2 | A-1 | 100 | B-2 | 1.8 | C-2 | 5 | D-2 | 0.3 | E-1/E-2/E-3 | 385/165/100 |
| Example 7 | | | | | | | | | | | |
| Synthesis | J-3 | A-2 | 100 | B-2 | 1.8 | C-3 | 5 | D-3 | 0.3 | E-1/E-2/E-3 | 385/165/100 |
| Example 8 | | | | | | | | | | | |
| Synthesis | J-4 | A-2 | 100 | B-3 | 3.7 | C-4 | 5 | D-3 | 0.3 | E-1/E-2/E-3 | 385/165/100 |
| Example 9 | | | | | | | | | | | |
| Synthesis | J-5 | A-3 | 100 | B-1 | 1.8 | C-1 | 5 | D-3 | 0.3 | E-1/E-2/E-3 | 385/165/100 |
| Example 10 | | | | | | | | | | | |
| Synthesis | J-6 | A-4 | 100 | B-3 | 3.7 | C-2 | 5 | D-3 | 0.3 | E-1/E-2/E-3 | 385/165/100 |
| Example 11 | | | | | | | | | | | |
| Synthesis | J-7 | A-5 | 100 | B-2 | 1.8 | C-4 | 5 | D-1 | 0.3 | E-1/E-2/E-3 | 385/165/100 |
| Example 12 | | | | | | | | | | | |
| Synthesis | J-8 | A-1 | 100 | B-1 | 1.8 | CC-1 | 5 | D-1 | 0.3 | E-1/E-2/E-3 | 385/165/100 |
| Example 13 | | | | | | | | | | | |
| Synthesis | J-9 | A-1 | 100 | B-1 | 1.8 | — | — | D-1 | 0.3 | E-1/E-2/E-3 | 385/165/100 |
| Example 14 | | | | | | | | | | | |
| Synthesis | J-10 | A-2 | 100 | B-3 | 3.7 | — | — | D-3 | 0.3 | E-1/E-2/E-3 | 385/165/100 |
| Example 15 | | | | | | | | | | | |

### Formation of Resist Pattern

### KrF Exposure

Silicon Wafer Substrate

### Examples 1 to 10

A resist film having a film thickness of 540 nm was provided on an 8-inch silicon wafer by applying each photoresist composition shown in Table 3 below on the 8-inch silicon wafer, followed by PB at 90° C. for 60 sec and cooling at 23° C. for 30 sec. Then, an exposure was carried out under the best focus condition using a KrF excimer laser scanner (NSR S203B, manufactured by Nikon Corporation), under optical conditions involving NA of 0.68, sigma of 0.75 and Conventional. Then, PEB was carried out for 60 sec at the PEB temperature shown in Table 3 below, followed by cooling at 23° C. for 30 sec. Subsequently, a puddle development was carried out for 30 sec using butyl acetate as a developer solution, followed by rinsing for 7 sec with 4-methyl-2-pentanol as a rinse agent. Then, spin-drying at 2,000 rpm for 15 sec was carried out, whereby a resist pattern having 250 nm-lines and 2,500 nm-pitches was formed.

### Evaluations

The photoresist compositions were evaluated in regard to sensitivity, as well as inhibition of the peeling of the pattern and inhibition of scums in accordance with the following methods on the resist patterns thus formed. The results of the evaluations are shown together in Table 3.

### Sensitivity

An exposure dose at which a line pattern having 250 nm-lines and 2,500 nm-pitches was formed was defined as an optimum exposure dose, and the optimum exposure dose was designated as sensitivity (mJ/cm²). It is to be noted that for a line-width measurement of the resist pattern, a scanning electron microscope (S-9380, manufactured by Hitachi High-Technologies Corporation) was used.

### Inhibition of Peeling

The pattern having 250 nm-lines and 2,500 nm-pitches which was resolved at the optimum exposure dose was observed from above the pattern using the scanning electron microscope. The observation was carried out at arbitrary 100 points in total at a magnification of ×100 k, and peeling of the pattern was determined as to whether or not the peeling occurred. The inhibition of peeling was evaluated as: “A” when peeling was not found at any place; and “B” when peeling occurred at least one place.

### Inhibition of Scums

A cross-sectional shape of the pattern having 250 nm-lines and 2,500 nm-pitches which was resolved at the optimum exposure dose was observed using a scanning electron microscope (S-4800, manufactured by Hitachi High-Technologies Corporation). The inhibition of scums was evaluated as: “A” when scums were not found in the space portion of the resist line pattern; and “B” when scums were found therein.

TABLE 3

| | | PEB | Results of evaluations | | |
|---|---|---|---|---|---|
| | | temp- | | inhibition | |
| | Photoresist | erature | sensitivity | of | inhibition |
| | composition | (° C.) | (mJ/cm²) | peeling | of scums |
| Example 1 | J-1 | 115 | 56.0 | A | A |
| Example 2 | J-2 | 115 | 61.0 | A | A |
| Example 3 | J-3 | 105 | 52.0 | A | A |
| Example 4 | J-4 | 105 | 47.0 | A | A |
| Example 5 | J-5 | 105 | 50.0 | A | A |
| Example 6 | J-6 | 105 | 42.0 | A | A |
| Example 7 | J-7 | 100 | 60.0 | A | A |
| Example 8 | J-8 | 115 | 57.0 | B | A |

| | | | |
|---|---|---|---|
| Example 9 | J-9 | 115 | pattern evaluation failed |
| Example 10 | J-10 | 105 | pattern evaluation failed |

### Substrate-Dependency

### Examples 11 to 16

Resist patterns were formed in a similar manner to Examples 1 to 10, with the PEB temperature setting of 115° C. using various substrates shown in Table 4 in place of the silicon wafer described above as the substrate, and the photoresist compositions shown in Table 4. Then evaluations were made in a similar manner to Examples 1 to 10. The results of the evaluations are shown together in Table 4.

TABLE 4

| | | | Results of evaluations | | |
|---|---|---|---|---|---|
| | | | | inhibition | |
| | Photoresist | | sensitivity | of | inhibition |
| | composition | Substrate | (mJ/cm²) | peeling | of scums |
| Example 1 | J-1 | Bare-Si | 56.0 | A | A |
| Example 11 | J-1 | SiO₂ | 55.0 | A | A |
| Example 12 | J-1 | SiN | 57.0 | A | A |
| Example 8 | J-8 | Bare-Si | 57.0 | B | A |
| Example 13 | J-8 | SiO₂ | 55.0 | B | A |
| Example 14 | J-8 | SiN | 59.0 | B | A |

| | | | |
|---|---|---|---|
| Example 9 | J-9 | Bare-Si | pattern evaluation failed |
| Example 15 | J-9 | SiO₂ | pattern evaluation failed |
| Example 16 | J-9 | SiN | pattern evaluation failed |

Developer Solution- and Rinse Agent-Dependency

### Examples 17 to 26

Resist patterns were formed in a similar manner to Examples 1 to 10, with the PEB temperature setting of 105° C. using: various developer solutions shown in Table 5 below in place of butyl acetate described above as the developer solution; various rinse agents shown in Table 5 in place of 4-methyl-2-pentanol described above as the rinse agent; and the photoresist compositions shown in Table 5. Then evaluations were made in a similar manner to Examples 1 to 10. The results of the evaluations are shown together in Table 5.

TABLE 5

| | | | | Results of evaluations | | |
|---|---|---|---|---|---|---|
| | | | | | inhibition | |
| | Photoresist | | Rinse | sensitivity | of | inhibition |
| | composition | Developer solution | agent | (mJ/cm²) | peeling | of scums |
| Example 4 | J-4 | butyl acetate | 4-methyl- | 47.0 | A | A |
| | | | 2-pentanol | | | |
| Example 17 | J-4 | isoamyl acetate | 1-hexanol | 52.0 | A | A |
| Example 18 | J-4 | benzyl acetate | diisoamyl | 54.0 | A | A |
| | | | ether | | | |
| Example 19 | J-4 | methyl amyl ketone | 4-methyl- | 61.0 | A | A |
| | | | 2-pentanol | | | |
| Example 20 | J-4 | methyl amyl ketone with 1 wt | diisoamyl | 54.0 | A | A |
| | | % trioctylamine added | ether | | | |
| Example 21 | J-4 | anisole | diisoamyl | 59.0 | A | A |
| | | | ether | | | |

| | | | | |
|---|---|---|---|---|
| Example 10 | J-10 | butyl acetate | 4-methyl- | pattern evaluation failed |
| | | | 2-pentanol | |
| Example 22 | J-10 | isoamyl acetate | 1-hexanol | pattern evaluation failed |
| Example 23 | J-10 | benzyl acetate | diisoamyl | pattern evaluation failed |
| | | | ether | |
| Example 24 | J-10 | methyl amyl ketone | 4-methyl- | pattern evaluation failed |
| | | | 2-pentanol | |
| Example 25 | J-10 | methyl amyl ketone with 1 wt | diisoamyl | pattern evaluation failed |
| | | % trioctylamine added | ether | |
| Example 26 | J-10 | anisole | diisoamyl | pattern evaluation failed |
| | | | ether | |

### ArF Exposure

### Examples 27 to 33

Resist patterns having 250 nm-lines and 2,500 nm-pitches were formed in a similar manner to the KrF Exposure described above except that: an exposure was carried out under the best focus condition using the photoresist compositions shown in Table 6 below, and an ArF excimer laser scanner (NSR S306C, manufactured by Nikon Corporation) as an exposure system, under optical conditions involving NA of 0.75, sigma of 0.80 and Conventional; and the PEB temperature setting was as specified in Table 6. Then, evaluations were made in similar manner to Examples 1 to 10. The results of the evaluations are shown together in Table 6.

TABLE 6

| | | PEB | Results of evaluations | | |
|---|---|---|---|---|---|
| | | temp- | | inhibition | |
| | Photoresist | erature | sensitivity | of | inhibition |
| | composition | (° C.) | (mJ/cm²) | peeling | of scums |
| Example 27 | J-1 | 115 | 48.0 | A | A |
| Example 28 | J-4 | 105 | 40.0 | A | A |
| Example 29 | J-5 | 105 | 43.0 | A | A |
| Example 30 | J-6 | 105 | 36.0 | A | A |
| Example 31 | J-8 | 115 | 48.0 | B | A |

| | | | |
|---|---|---|---|
| Example 32 | J-9 | 115 | pattern evaluation failed |
| Example 33 | J-10 | 105 | pattern evaluation failed |

As is clear from the results shown in Tables 3 to 6, the method for producing a semiconductor element and the ion implantation method enable a resist pattern exhibiting inhibited peeling of the pattern, and inhibited generation of scums to be formed on substrates made from various materials using various developer solutions and rinse agents, in any case of the exposure carried out by the KrF exposure or the ArF exposure. It is believed that according to the method for producing a semiconductor element and the ion implantation method of the embodiment of the present invention, ion implantation can be achieved in a desired region of an inorganic substrate by using such a superior resist pattern as a mask.

The method for producing a semiconductor element according to the embodiment of the present invention enables a resist pattern exhibiting inhibited peeling of the pattern, and inhibited generation of scums to be formed, and by using such a superior resist pattern as a mask, a semiconductor element including an inorganic substrate into which ions are implanted in a desired region can be produced. The ion implantation method according to the embodiment of the present invention enables ions to be implantation in a desired region of an inorganic substrate. Therefore, the embodiments of the present invention can be suitably used in manufacture of semiconductor devices and the like, and can improve performances, reliability, a process yield and the like of the products.

Obviously, numerous modifications and variations of the present invention are possible in light of the above teachings. It is therefore to be understood that within the scope of the appended claims, the invention may be practiced otherwise than as specifically described herein.

1. A method for producing a semiconductor element, comprising:
applying a photoresist composition on a surface of an inorganic substrate to provide a resist film, the photoresist composition comprising: a polymer comprising an acid-labile group; and an acid generator;
exposing the resist film;
developing the exposed resist film with a developer solution comprising an organic solvent to form a negative resist pattern; and
implanting ions into the inorganic substrate using the negative resist pattern as a mask.

2. The method according to claim 1, wherein the photoresist composition further comprises:
a compound comprising a carboxy group, a sulfo group, a group represented by formula (i), a group capable of generating the carboxy group, the sulfo group or the group represented by the formula (i) by an action of an acid, a lactonic carbonyloxy group or a combination thereof, the compound having a molecular weight of no greater than 1,000, 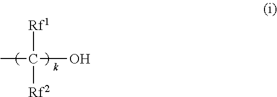
wherein in the formula (i),
Rf¹ and Rf² each independently represent a hydrogen atom, a fluorine atom or a perfluoroalkyl group; and
k is an integer of 1 to 5,
wherein in a case where k is no less than 2, a plurality of Rf¹s are each identical or different, and a plurality of Rf²s are each identical or different, and wherein at least one of Rf¹ and Rf² bonding to the carbon atom adjacent to the hydroxy group does not represent a hydrogen atom, and
wherein an amount of the compound is no less than 0.1 parts by mass and no greater than 30 parts by mass with respect to 100 parts by mass of the polymer.

3. The method according to claim 2, wherein the compound comprises an alicyclic skeleton.

4. The method according to claim 3, wherein the alicyclic skeleton is an adamantane skeleton, a norbornane skeleton, a steroid skeleton or a combination thereof.

5. The method according to claim 4, wherein the compound is a compound represented by formula (1), a compound represented by formula (2-1), a compound represented by formula (2-2), a compound represented by formula (3) or a combination thereof: 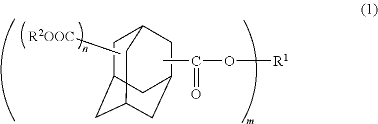
wherein in the formula (1),
R¹ represents a hydrogen atom or an acid-labile group having a valency of m;
R² represents a hydrogen atom or a monovalent acid-labile group;
m is an integer of 1 to 4; and
n is an integer of 0 to 15,
wherein in a case where R² is present in a plurality of number, a plurality of R^{e}s are each identical or different, 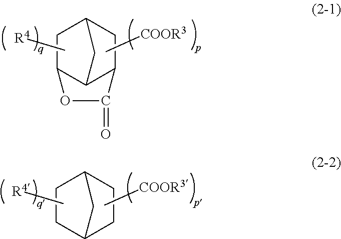
in the formulae (2-1) and (2-2),
R³ and R^{3′} each independently represent a hydrogen atom, an alkyl group having 1 to 5 carbon atoms or a monovalent acid-labile group;
R⁴ and R^{4′} each independently represent a hydroxy group, an alkoxy group or the group represented by the formula (i);
p is an integer of 0 to 10;
q is an integer of 0 to 10;
p′ is an integer of 0 to 12; and
q′ is an integer of 0 to 12,
wherein a sum of p and q is no less than zero and no greater than 10, a sum of p′ and q′ is no less than 1 and no greater than 12,
wherein in a case where R³, R^{3′}, R⁴ and R^{4′} are each present in a plurality of number, a plurality of R^{a}s are each identical or different, a plurality of R^{3′}s are each identical or different, a plurality of R⁴s are each identical or different and a plurality of R^{4′}s are each identical or different, and
wherein at least one of R^{3′} and R^{4′} represents a hydrogen atom, a monovalent acid-labile group or the group represented by the formula (i), and 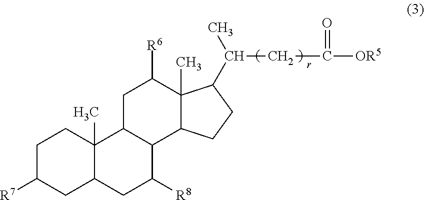
in the formula (3),
R⁵ represents a hydrogen atom, a monovalent acid-labile group, or a monovalent organic group comprising an acid-labile group;
R⁶, R⁷ and R⁸ each independently represent a hydrogen atom, —OH or ═O; and
r is 1 or 2.

6. An ion implantation method comprising:
applying a photoresist composition on a surface of an inorganic substrate to provide a resist film, the photoresist composition comprising: a polymer comprising an acid-labile group; and an acid generator;
exposing the resist film;
developing the exposed resist film with a developer solution comprising an organic solvent to form a negative resist pattern; and
implanting ions into the inorganic substrate using the negative resist pattern as a mask.

7. The ion implantation method according to claim 6, wherein the photoresist composition further comprises:
a compound comprising a carboxy group, a sulfo group, a group represented by formula (i), a group capable of generating the carboxy group, the sulfo group or the group represented by the formula (i) by an action of an acid, a lactonic carbonyloxy group or a combination thereof, the compound having a molecular weight of no greater than 1,000, 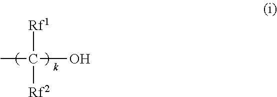
wherein in the formula (i),
Rf¹ and Rf² each independently represent a hydrogen atom, a fluorine atom or a perfluoroalkyl group; and
k is an integer of 1 to 5,
wherein in a case where k is no less than 2, a plurality of Rf¹s are each identical or different, and a plurality of Rf²s are each identical or different, and wherein at least one of Rf¹ and Rf² bonding to the carbon atom adjacent to the hydroxy group does not represent a hydrogen atom, and
wherein an amount of the compound is no less than 0.1 parts by mass and no greater than 30 parts by mass with respect to 100 parts by mass of the polymer.

8. The ion implantation method according to claim 7, wherein the compound comprises an alicyclic skeleton.

9. The ion implantation method according to claim 8, wherein the alicyclic skeleton is an adamantane skeleton, a norbornane skeleton, a steroid skeleton or a combination thereof.

10. The ion implantation method according to claim 9, wherein the compound is a compound represented by formula (1), a compound represented by formula (2-1), a compound represented by formula (2-2), a compound represented by formula (3) or a combination thereof: 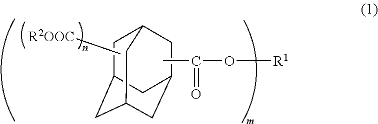
wherein in the formula (1),
R¹ represents a hydrogen atom or an acid-labile group having a valency of m;
R² represents a hydrogen atom or a monovalent acid-labile group;
m is an integer of 1 to 4; and
n is an integer of 0 to 15,
wherein in a case where R² is present in a plurality of number, a plurality of R^{e}s are each identical or different, 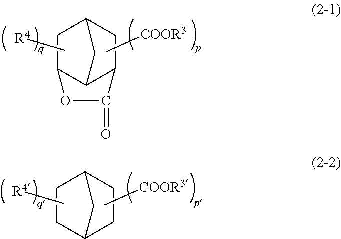
in the formulae (2-1) and (2-2),
R³ and R^{3′} each independently represent a hydrogen atom, an alkyl group having 1 to 5 carbon atoms or a monovalent acid-labile group;
R⁴ and R^{4′} each independently represent a hydroxy group, an alkoxy group or the group represented by the formula (i);
p is an integer of 0 to 10;
q is an integer of 0 to 10;
p′ is an integer of 0 to 12; and
q′ is an integer of 0 to 12,
wherein a sum of p and q is no less than zero and no greater than 10, a sum of p′ and q′ is no less than 1 and no greater than 12,
wherein in a case where R³, R^{3′}, R⁴ and R^{4′} are each present in a plurality of number, a plurality of R³s are each identical or different, a plurality of R^{3′}s are each identical or different, a plurality of R⁴s are each identical or different and a plurality of R^{4′}s are each identical or different, and
wherein at least one of R^{3′} and R^{4′} represents a hydrogen atom, a monovalent acid-labile group or the group represented by the formula (i), and 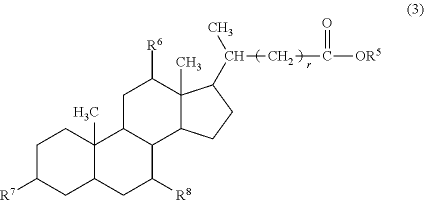
in the formula (3),
R⁵ represents a hydrogen atom, a monovalent acid-labile group, or a monovalent organic group comprising an acid-labile group;
R⁶, R⁷ and R⁸ each independently represent a hydrogen atom, —OH or ═O; and
r is 1 or 2.
